(19) United States
(12) Patent Application Publication
(10) Pub. No.: US 2026/0271245 A1
(43) Pub. Date: Sep. 10, 2026

(54) FACILITY MANAGEMENT SYSTEM AND METHODS

(71) Applicant: Phaidra Inc., Seattle, WA (US)

(72) Inventors: Kenzo Spaulding, Seattle, WA (US); Vedavyas Panneershelvam, Burnaby, CA (US); Christopher R. Vause, Austin, TX (US)

(73) Assignee: Phaidra Inc., Seattle, WA (US)

(21) Appl. No.: 19/427,459

(22) Filed: Dec. 19, 2025

Related U.S. Application Data
(60) Provisional application No. 63/736,305, filed on Dec. 19, 2024.
(60) Provisional application No. 63/737,260, filed on Dec. 20, 2024.

(51) Int. Cl. H05K 7/20; G05B 23/02

(52) U.S. Cl. CPC H05K 7/20836; G05B 23/0291

(57) ABSTRACT

In variants, an ML-based control system for an industrial facility can include a remote control plane, a client, a set of agents, data processing modules, an optional data store, a telemetry module, a learning module, and/or any other suitable components. In variants, the set of agents can include a facility agent, a set of local cooling agents, and/or any other suitable agents. In variants, the set of agents can include system state approximators and decision models learned via reinforcement learning. The ML-based control system can control components of the industrial facility by predicting and/or determining component setpoints based on power load and/or heat load of the industrial facility.

### CROSS-REFERENCE TO RELATED APPLICATIONS

This application claims the benefit of U.S. Provisional Application No. 63/737,260 filed 20 Dec. 2024 and U.S. Provisional Application No. 63/736,305 filed 19 Dec. 2024, which are each incorporated in their entirety by this reference.

### TECHNICAL FIELD

This invention relates generally to the controls field, and more specifically to a new and useful ML-based facility management system in the controls field.

### BRIEF DESCRIPTION OF THE FIGURES

FIG. 1 is a schematic representation of a variant of the system.

FIG. 2 is a schematic representation of a variant of a subsystem (e.g., local cooling loops, etc.) of the system.

FIG. 3 is a schematic representation of a variant of the system.

FIG. 4 is a schematic representation of a variant of the agent where the agent is a reinforcement learning model.

FIG. 5 is a schematic representation of a variant of the agent.

FIG. 6 is a schematic representation of a variant of the method.

### DETAILED DESCRIPTION

The following description of the embodiments of the invention is not intended to limit the invention to these embodiments, but rather to enable any person skilled in the art to make and use this invention.

### 1. Overview

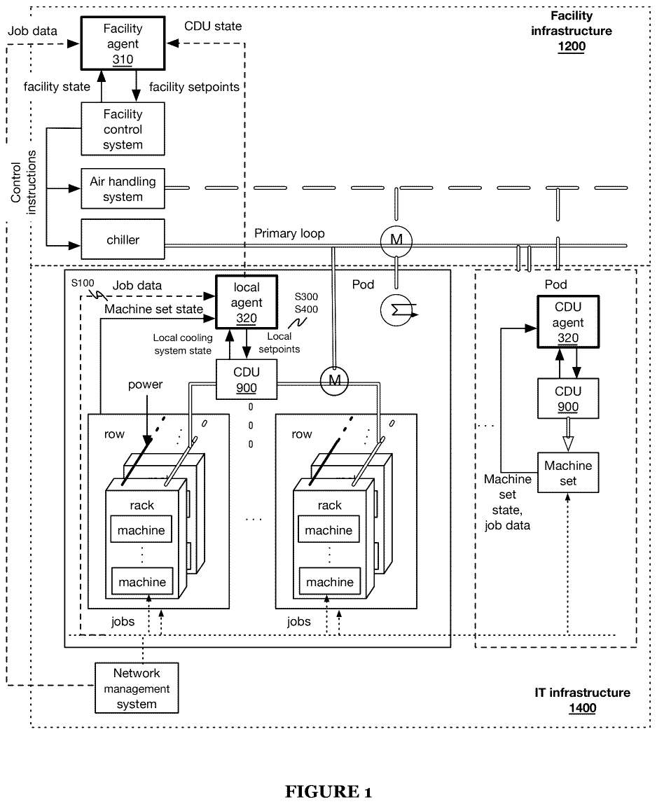

As shown in FIG. 1, variants of the ML-based control system can include a remote control plane, a client, a set of agents, data processing modules, an optional data store, a telemetry module, a learning module, and/or any other suitable components. In variants, the set of agents can include a facility agent, a set of local cooling agents, and/or any other suitable agents. The ML-based control system functions to control components of an industrial facility by predicting and/or determining component setpoints (e.g., for environment conditioning system control, etc.).

In variants, the set of local cooling agents can determine local setpoints for a given local cooling system (e.g., for a CDU, for a liquid cooling system, etc.), while a facility agent can function as a supervisory controller that monitors system states and manages operational parameters. In variants, a cooling loop (e.g., a closed thermal system which can include a set of CDUs, a branch from a primary cooling loop for local cooling, etc.) can be controlled by a local cooling agent. A local cooling agent can include prediction models and/or approximators (e.g., state approximators, physics-based models, thermal response models, power models, etc.), decision and/or action models and/or modules (e.g. reinforcement learning model, heuristic modules, policies, etc.) and/or any suitable components.

In a specific example, a local cooling agent can receive a system state (e.g., temperature measurements for the cooling loop, CDU outlet temperatures, CDU inlet temperatures, power consumption, power provision, etc.) for a physical control domain (e.g., technical loop, cooling loop, etc.), optionally predict a thermal response and/or load for each CDU in the physical control domain based on the system state (e.g., using a state approximator, thermal load triangle model, thermal response model, physics-based model, etc.), determine a set of cooling loop and/or CDU setpoints (e.g., based on the predicted thermal response, based on the system state, etc.), and control the cooling loop and/or CDUs according to the setpoints (e.g., by setting supply temperature targets, etc.). In a specific example, the liquid cooling agent can preemptively lower the supply temperature setpoint to accommodate for an anticipated thermal load due to an increase in power consumption (e.g., detected power spike). In variants, each liquid cooling agent and/or cooling loop can be controlled independently of each other (e.g., without insight into the control domain states of the other control domains; based only on the system state of the respective control domain). In variants, the physical control domain can include multiple CDUs, each cooling one or more racks of compute hardware. In examples of these variants, each liquid cooling agent can include a different model (e.g., thermal load prediction model) for each CDU.

In variants, the technology can include an on-premises inference agent that runs locally at customer sites, with data normalization and processing capabilities packaged into a single binary. The system maintains cloud connectivity for model training and updates while performing inference locally. The architecture includes a local buffer for storing state information and features, with configurable time-to-live settings based on tag configurations. The deployment can be handled through Docker containers or VM images, with options for both hybrid cloud-connected and air-gapped installations. Security features include signed binaries, firewall configurations, and potential data diodes for one-way communication. The system supports multiple agent interfaces and versions, allowing for backwards compatibility and gradual updates. Components can be split between trusted and untrusted network zones depending on security requirements.

Variants of the on-premises architecture can differ from conventional ML-based control methods by implementing a hybrid approach where inference runs locally while training remains in the cloud. For example, these variants can package data processing and inference into a single binary that runs on-premises, while maintaining cloud-based model training and updates. This differs from traditional approaches that typically run entirely in the cloud or entirely on-premises. The hybrid architecture can enable faster control frequencies for time-sensitive operations while still leveraging cloud capabilities for computation-intensive training. The architecture can also include unique elements like a data diode for one-way data flow to the cloud, local state buffers for inference, and modular agents that can be deployed close to control points, providing better security and reliability compared to pure cloud solutions.

### 2. System

In variants, the ML control system: can include a remote control plane 100, a client 200, a set of agents 300 (e.g. local agents, facility agents, etc.), data processing modules 400, an optional data store 500, a telemetry module 600, a learning module 700, and/or any other suitable components. In variants, as shown in FIG. 1, the ML control system can include a set of agents, which can include a facility agent 310, a set of local cooling agents 320, and/or any other suitable agents. The ML control system can function as a supervisory controller for facility infrastructure and IT physical infrastructure control.

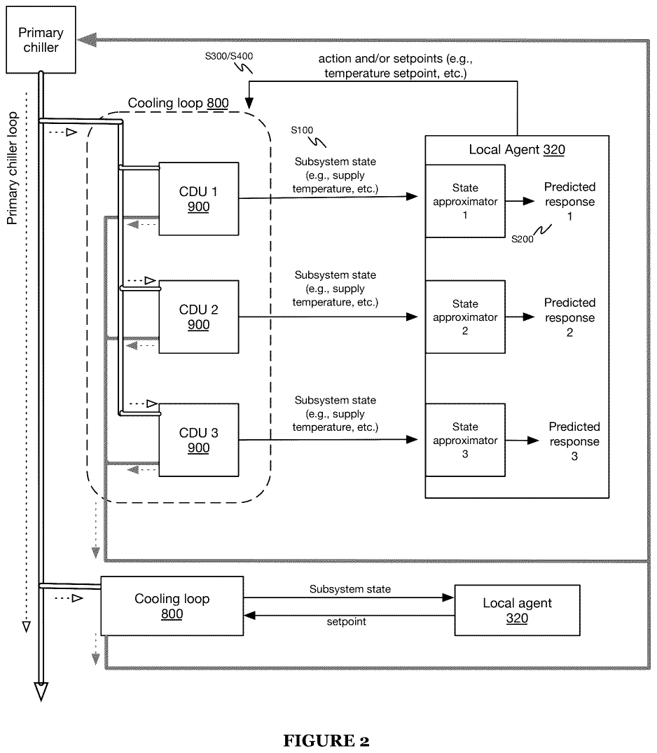

In variants, the ML control system can be used with an industrial facility 1000. The ML control system can be used to control an industrial facility (e.g., example shown in FIG. 2) and/or can otherwise interact with the industrial facility. The industrial facility is preferably an IT facility, and more preferably a data center, but can alternatively be a regional cluster, a global network, a data hall, enterprise data center, colocation data centers (e.g., colos), hyperscale data centers, cloud data centers, managed hosting data centers, and/or any other suitable industrial facility type. In variants, the industrial facility can include a facility infrastructure 1200; an information technology infrastructure 1400 and/or any other suitable components.

The facility infrastructure 1200 can function to physically support IT infrastructure operation (e.g., manage thermal load, power provision, etc.) and/or any other suitable infrastructure support functions. The facility infrastructure preferably includes physical systems, but can additionally or alternatively include data systems. In variants, the facility infrastructure can include an environment conditioning system (e.g., HVAC, ambient control, etc.); facility infrastructure subsystems; a set of control systems, and/or any other suitable components.

The environment conditioning system (e.g., HVAC, ambient control, etc.) can function to control the internal and/or external environment and/or any other suitable environment. The environment conditioning system can control any suitable environmental parameters and/or conditions. The environment conditioning system (e.g., HVAC, ambient control, etc.) can include: pumps (e.g., heat pumps, fluid pumps, etc.), fans, heating units, cooling units (e.g., Peltier pumps, heat pumps, chillers, etc.), and/or any other suitable components. However, the environment conditioning system (e.g., HVAC, ambient control, etc.) may be otherwise configured.

The facility infrastructure subsystems can include one or more: cooling systems (e.g., chillers, air handling systems such as computer room air handlers (CRAHs), etc.); power systems (e.g., uninterruptible power supplies, power distribution units, backup generators, etc.); environmental controls (e.g., humidity regulation, fire suppression, air circulation, etc.); and/or any other suitable subsystems. The facility infrastructure subsystems can include: pumps (e.g., heat pumps, fluid pumps, etc.), heat exchangers, fans, heating units, cooling units (e.g., Peltier pumps, heat pumps, chillers, etc.), valves, plenums, sensors (e.g., temperature, pressure, flow rate, humidity, etc.), and/or any other suitable components. In variants, facility infrastructure subsystems can include compute hardware (e.g., server) racks, cooling loops (e.g., facility-level, room-level, aisle-level, rack-level, device-level, etc.), and/other sets of interacting components within the industrial facility.

In an example, a chiller controls facility-level cooling, while CRAHs control room-level cooling. The CRAHs can be thermally connected to the chiller loop (e.g., blow air over an exposed surface of the chiller loop to cool the room, dump heat into the chiller loop, etc.), or be otherwise thermally connected to the chiller loop. However, the facility infrastructure subsystems may be otherwise configured.

The set of control systems (e.g., facility control systems) can function to control the facility infrastructure and/or any other suitable facility components. The set of control systems can function to control the facility infrastructure subsystems, environment conditioning system, compute hardware (e.g., computing devices, processing systems, etc.), local cooling systems, and/or any other suitable systems within the industrial facility. The facility control systems can include: local control systems (LCS), building management systems (e.g., that control the environment conditioning system), load managers and/or load balancers (e.g., that control data or job workload distribution across compute hardware), local cooling control (e.g., a CPU on the compute hardware or rack that controls the local cooling based on a current or predicted compute hardware thermal state, etc.), and/or any other suitable control systems.

Each control system can be specific to and control a different facility subsystem, and/or alternatively control multiple facility subsystems. In a first example, the facility infrastructure includes a cooling control system that controls all cooling subsystem components and a power control system that controls all the power subsystem components. In a second example, the facility infrastructure includes a chiller control system that controls the chillers and an air handling control system that controls the air handling subsystem. In a third example, the facility infrastructure can include a hierarchical structure of control systems, which can include facility and/or room-level control systems and rack and/or device-level control systems. When the facility control system is specific to a subsystem, different instances of the same subsystem type can be controlled by the same facility control system and/or different facility control systems; alternatively, the facility control system can be subsystem agnostic or otherwise associated with subsystems. In variants, each control system can be independent from each other, dependent on each other, and/or otherwise related. In variants, the control systems can generate control instructions based on the control instructions determined from another control system. For example, in a variant, a cooling control system can generate controls based on the load manager (e.g., workload scheduler, etc.). In another variant, cooling control systems for separate cooling loops can be independent, such that each cooling control system for each cooling loop generates control instructions based only on its cooling loop. However, the control systems can be otherwise related.

The set of control systems can generate the setpoint and/or low-level control instructions (e.g., pump voltage, pump rate, cooling unit voltage or current, etc.) for the respective facility component, group thereof, subsystem, and/or any other suitable control instructions. The control instructions are preferably generated based on the current state of the controlled facility component set and a target setpoint (e.g., operating target), but can alternatively be generated according to a predetermined schedule or otherwise generated. Examples of facility setpoints can include: target measurement values, target component states, target measurement rates of change, differential pressure setpoint for pumps, supply temperature setpoint for cooling systems, valve positions for primary and secondary cooling loops, and/or any other suitable setpoints. In an example, the facility control systems iteratively modulates the chiller power until the measured temperature substantially meets a temperature setpoint.

The set of control systems can be behind a firewall and/or in any other suitable location relative to the firewall. The set of control systems can run all or portions of the control system set on a local machine (e.g., within the industrial facility), but can alternatively run on a remote computing system. The set of existing control systems is preferably located on a separate machine from the compute hardware set, but can alternatively be located on a machine within the compute hardware set. The set of existing control systems can include local machines that can be used: a server, CPU, GPU, microprocessor, ASIC, cluster, and/or any other suitable local machine type. The set of existing control systems can alternatively run on a local cloud (e.g., can be local or remote from the industrial facility) and/or any other suitable location.

An industrial facility can include one or more control systems. The number of control systems can be determined based on the requirements of the industrial facility. The facility control system can include: a PID controller (e.g., that reacts to deviations in supply temperature from control setpoints), cascaded PID controllers, and/or any other suitable control system type.

However, the set of control systems can be otherwise configured.

However, the facility infrastructure can be otherwise configured.

The information technology infrastructure 1400 can function to run applications and workloads, process data, store data, transmit data, and/or any other suitable information technology functions.

The information technology infrastructure operates within an environment managed by facility infrastructure. In variants, the information technology infrastructure can include a set of compute hardware; a local cooling system; power distribution units; storage systems; networking equipment (e.g., routers, data switches, load managers, firewalls, network interface cards, etc.); network management systems; and/or any other suitable components.

The set of compute hardware can function to process data (e.g., jobs) and/or any other suitable data types. In variants, the set of compute hardware can function to run customer applications and workloads instead of datacenter infrastructure management tasks. The set of compute hardware can run any suitable customer applications and/or any suitable customer workloads. The set of compute hardware can include processing systems (e.g., computers) that are not involved in controlling datacenter operations and/or any other suitable processing systems. Alternatively and/or additionally, a set of compute hardware can function as a facility controller. The compute hardware can include: physical machines, bare metal machines, other processing systems, and/or any other suitable machines. The machines can include one or more of a: GPU, CPU, TPU, IPU, microprocessor, server, and/or any other suitable processing unit type.

The set of compute hardware can be organized into a hierarchy of control domains (e.g., machine subsets). The hierarchy can include: machines (e.g., individual computing unit), racks (e.g., group of machines mounted to a common physical enclosure), rows (e.g., group of racks with shared infrastructure, such as cooling or power, etc.) and/or aisles, pods (e.g., group of collocated rows or racks), zones or regions (e.g., groups of collocated rows), data halls (e.g., large room with multiple zones), data centers (e.g., facility with one or more data halls), and/or regional center sets (e.g., geographical region with multiple data centers).

In variants, the set of compute hardware can be directly cooled by local cooling systems (e.g., liquid cooling systems), ambiently cooled by the environment conditioning systems, and/or any other suitable cooling methods. However, the set of compute hardware may be otherwise configured.

In a first example, a rack's local cooling system is thermally connected to the chiller loop. In a second example, a rack is thermally connected (e.g., via convection, radiation, etc.) to the ambient environment, wherein the ambient environment is controlled by the air handling system. In examples, the facility infrastructure manages the thermal load output by the information technology infrastructure.

In a specific example, the information technology infrastructure can include server racks organized into pods, with each pod containing racks of compute modules (e.g., 10 racks) arranged in rows (e.g., 2 rows), with multiple machines per rack. The cooling system for each pod can include a local cooling system (e.g., including a coolant manifold and a cooling distribution unit) on the liquid cooling side and computer room air handlers (CRAHs) on the air side. Each pod can include one active cooling distribution unit (CDU).

The power distribution to each pod's machines can be through a three-phase AC system that feeds rectifiers that convert the AC voltage to DC voltage at the rack level. The information technology infrastructure can include networking infrastructure (e.g., workload scheduler, load manager, etc.) that monitors the physical and/or data state of each machine or group thereof (e.g., rack, pod, etc.) and distributes the computational workload across the compute resources.

However, the set of compute hardware may be otherwise configured.

The local cooling system can function to manage the thermal load output by the information technology infrastructure (IT infrastructure) or subset thereof. The local cooling system can be a part of or separate from the facility infrastructure. In variants, the local cooling system can be a subsystem of the facility infrastructure. The local cooling system is preferably specific to a pod (e.g., wherein the local cooling system manages the thermal load of the machines within the pod), but can alternatively be specific to a rack, row, zone, and/or any other suitable coverage area.

The local cooling system preferably removes waste heat from the compute hardware using a coolant, but can alternatively remove waste heat using any other suitable method. The coolant can be a liquid, gas (e.g., air), and/or any other suitable coolant type. The local cooling system can remove waste heat through conduction, convection, radiation, and/or any other suitable heat removal method.

In variants, the facility infrastructure 1200 can also include the IT infrastructure's 1400 local cooling systems, but can alternatively exclude the IT infrastructure's local cooling systems, be communicatively separate from the local cooling systems (e.g., have separate controllers, not be in direct data communication, etc.), and/or otherwise configured. In an example, the facility infrastructure is physically connected to the local cooling systems (e.g., since the local cooling systems use the facility infrastructure as a heat sink for the machines), but are communicatively isolated from each other (e.g., the facility infrastructure does not send data, such as setpoints, to the local cooling systems). In another example, the facility infrastructure can communicate with (e.g., control) the local cooling system.

In variants, the local cooling systems can be configured as a set of cooling loops 800, as shown for example in FIG. 2. In variants, the cooling loops can have hierarchical structure. For example, primary cooling loops can include facility-level cooling loops (e.g., which may be part of the facility infrastructure, etc.), secondary cooling loops can include room-level, zone-level, row-level, and/or aisle-level cooling loops, and tertiary cooling loops can include device-level and/or rack-level cooling loops. However, the cooling loops can be organized in any suitable structure. In variants, a local cooling system can include device-level cooling loops, rack-level cooling loops, row-level cooling loops, aisle-level cooling loops, zone-level cooling loops, room-level loops, and/or any other suitable cooling loops. The ML control system can control each loop, each secondary loop, each technical loop, or any other suitable cooling loops.

In variants, a technical loop can be defined as a hardware-bounded thermal subsystem whose elements share a closed or semi-closed heat-transfer path, such as a set of CDUs, rack manifolds, supply/return piping, and associated compute hardware thermally coupled through one or more heat exchangers. Additionally or alternatively, a technical loop can be defined as the minimal set of hardware components whose thermal states are jointly influenced by a common control variable (e.g., a CDU supply-temperature setpoint or pump speed). In some embodiments, the technical loop corresponds to the smallest controllable unit for which the ML control agent generates setpoints, and can include one or more CDUs thermally coupled to one or more racks, compute nodes, and/or cooling branches. In variants, the control domain of a given ML control agent is defined by the hardware circuit boundaries of its assigned technical loop—for example, the segment of the facility cooling network beginning at a supply junction, passing through the CDUs and rack-manifold network serviced by those CDUs, and returning to a defined return junction. In an alternative definition, the technical loop can be the maximal set of components whose thermal state transitions exhibit coupled or correlated responses to actuator changes within that loop, thereby distinguishing it from other loops that do not share such thermal interactions. Because the technical loop is defined by physical fluid-routing and heat-transfer boundaries, it forms a natural computational boundary for ML-based control and allows the system to isolate prediction and actuation responsibilities to specific sets of components. In some examples, each technical loop includes at least one CDU and at least one thermally coupled computing device, but may include any number of CDUs, computing racks, manifolds, valves, and sensing points sufficient to define an independent control region.

In variants of the system, a local cooling loop can refer to a closed thermal system. In variants, a cooling loop can be a branch of the primary chiller loop (e.g., that receives coolant from a main chiller) wherein the branch can include a subset of components (e.g., CDUs, compute hardware, etc.) of the facility. In these variants, coolant from a primary cooling loop flows into the local cooling loop and absorbs heat from the compute hardware (e.g., via a heat exchanger). The heated coolant leaves the local cooling loop and into the return of the primary cooling loop where it can be taken to the chiller. Each cooling loop can include at least one CDU (e.g., 1 CDU, 2 CDUs, 3 CDUs, 4 CDUs, 5 CDUs, 10 CDUs, 20 CDUs, 30 CDUs, 40 CDUs, 50 CDUs, or any value and/or range therebetween.). In examples, a technical loop can be coextensive with a cooling loop (e.g., a loop containing a single CDU serving a single rack), or can be a sub-loop within a larger cooling branch (e.g., a CDU cluster servicing multiple racks through a shared manifold). Each technical loop can include a fixed set of actuators (e.g., pumps, valves, CDU heat-exchange elements) and a corresponding set of sensors (e.g., flowrate, pressure, supply temperature, return temperature, rack inlet/outlet temperatures) whose measurements define the control state for that loop. In variants, a technical loop can contain any number of CDUs per amount of compute hardware (e.g., one CDU per rack, one CDU per 2-10racks, or 2-5 CDUs supporting a high-density rack group), and any suitable mapping can be used to define the control domain.

In variants, the system can have a set of cooling loops in fluid connection to a primary chiller loop. The set of cooling loops can be in parallel, in series, and/or otherwise configured. Each cooling loop can be fluidly connected to the same coolant chiller and/or heat exchangers.

The local cooling system can include a set of cooling distribution units 900 (CDUs), a secondary cooling loop, an optional rack-level thermal manifold, a heat exchanger, a control valve set, a sensor set, and/or any other suitable components.

The cooling distribution unit 900 can function to control heat transfer between a primary heat sink and secondary cooling loop and/or any other suitable heat transfer functions. The cooling distribution unit can include a primary heat sink that is preferably a cooling system of the facility infrastructure (e.g., the chiller loop), but can alternatively be connected to another primary heat sink and/or any other suitable heat sink configuration.

The cooling distribution unit preferably includes a controller that regulates coolant flow through the secondary coolant loop and/or the rack-level thermal manifold and regulates IT infrastructure subset temperature, but can alternatively be otherwise configured. In an example, the controller can control valves, pumps, and/or other subcomponents of the local cooling system to meet a set of local cooling system setpoints.

The set of local cooling system setpoints can include: differential fluid pressure (DP), supply temperature of the coolant (supply temperature), flow rate (e.g., volumetric, mass, etc.), and/or any other suitable setpoints. The local cooling system setpoints are preferably received from the local cooling agent for the local cooling system, but can alternatively be a predetermined set of setpoints, be dynamically calculated based on the managed machines' state, and/or be otherwise determined

The cooling distribution unit (CDU) can actively modulate cooling parameters based on temperature feedback from the secondary cooling loop, wherein the secondary cooling loop can contain a glycol mixture circulating through the server racks. The CDU can interface with the primary chilled water loop through a plate and frame heat exchanger, maintaining fluidic isolation while enabling thermal transfer between the two loops. The CDU can adjust its operation to increase or decrease cooling capacity in response to heat load changes when temperature deviations are detected. The CDU can control rack cooling through two main set points based on feedback from these parameters. In variants, CDU coolant (e.g., water, glycol, mixtures thereof, etc.) can flow up through the CDU rack, flow down through the rack, flow in serpentine and/or boustrophedonic path through the rack, branch into parallel and/or perpendicular flow paths through the rack, and/or otherwise flow in the rack.

In variants, each cooling loop and/or local cooling system can include a set of cooling distribution units (CDUs). The CDUs in a cooling loop can be in sequence, in parallel, and/or otherwise configured.

However, the cooling distribution unit may be otherwise configured.

The secondary cooling loop can circulate coolant directly to rows, racks, machines, or other machine groups. The secondary cooling loop can remove heat from computing components through direct liquid cooling (e.g., wherein the secondary cooling loop immerses the machine or is conductively connected to a heat exchanger of the machine). The secondary cooling loop can be thermally connected to and fluidly isolated from the primary heatsink(s) (e.g., through the CDU, directly through exposure to ambient air, etc.), or otherwise connected to the primary heatsink(s). For example, the secondary cooling loop can be thermally connected to the primary cooling loop through a heat exchanger.

The secondary cooling loop can be thermally connected to and fluidly isolated from the machines, or otherwise connected to the machines. The thermal connection can enable heat transfer between the secondary cooling loop and the machines while maintaining fluid isolation between the secondary cooling loop and the machines.

The secondary cooling loop can include coolant, wherein the coolant can be: water, glycol (e.g., propylene glycol, ethylene glycol, etc.), oil, and/or any other suitable coolant type. The secondary cooling loop can include: pumps, valves, heat pumps, and/or any other suitable components.

However, the secondary cooling loop may be otherwise configured.

The optional rack-level thermal manifold can function to thermally connect the individual machines to the secondary cooling loop and/or provide any other suitable thermal connection functionality. The rack-level thermal manifold can include: manifolds, piping, fluid manifold, thermally conductive channels, and/or any other suitable thermal manifold components.

However, the rack-level thermal manifold may be otherwise configured.

The heat exchanger can function to exchange heat between the secondary cooling loop and the primary heat sink (e.g., chiller loop, local cooling loop, ambient environment, etc.). For example, the heat exchanger can facilitate thermal transfer between the secondary cooling loop and the primary heat sink. The heat exchanger can be thermally connected between a primary heat sink and a secondary cooling loop, or otherwise arranged. The heat exchanger can be a plate frame heat exchanger, but can alternatively be any other suitable type of heat exchanger.

However, the heat exchanger may be otherwise configured.

The control valve set can modulate flow rates and pressures between primary and secondary loops. The control valve set can maintain differential pressure and temperature setpoints and/or any other suitable control parameters. The control valve set can function to regulate flow characteristics between the primary and secondary loops and/or any other suitable control functions. However, the control valve set may be otherwise configured.

The sensor set can function to monitor system conditions and provide feedback for control adjustments. The sensor set can include: temperature sensors, pressure sensors, and/or any other suitable sensors. However, the sensor set may be otherwise configured.

However, the local cooling system may be otherwise configured.

The power distribution units can function to provide power to the compute hardware and/or any other suitable power distribution functions. In an example, the power distribution units can handle 120V 3-phase AC power. The power distribution units can be provided over rails, shared bus, and/or any other suitable distribution means. The power distribution units can include breakers to prevent machines from drawing too much power and overloading the circuits. The power distribution units can include power sensors (e.g., voltage sensors, current sensors, etc.) to monitor power draw and/or any other suitable monitoring functions.

However, the power distribution units may be otherwise configured.

The network management systems (e.g., workload management systems) can function to distribute the computational workload across the set of compute hardware and/or any other suitable computational resources. The network management systems can include a load manager and/or load balancer, cluster scheduler, resource manager, job schedulers, orchestrators, and/or any other suitable job scheduling service.

The load manager (e.g., load balancer, workload scheduler, workload orchestrator, etc.) functions to allocate computing resources and determine execution timing for submitted workloads across available compute hardware. In examples, the load manager can evaluate incoming job requests, analyze their resource requirements (e.g., compute, memory, network), and assign them to computing nodes (machines) based on predefined policies, priority levels, current system utilization, and/or other parameters. The load manager can continuously monitor system state and can preempt, migrate, and/or rebalance jobs to optimize resource utilization while maintaining service level agreements and/or workload constraints. The load manager can additionally and/or alternatively perform any other suitable job management functions.

The load manager can monitor power consumption signals at the rack and pod level, job queue characteristics including job types and sizes, network data transfer patterns such as data ingestion spikes, historical job runtime information and characteristics, pipelining operations within individual jobs, and/or any other suitable monitoring parameters. The monitored characteristics can include power metrics, queue metrics, network metrics, historical metrics, operational metrics, and/or any other suitable metrics for job scheduling purposes.

However, the load manager may be otherwise configured.

However, the network management systems may be otherwise configured.

However, the information technology infrastructure may be otherwise configured.

However, the industrial facility may be otherwise configured.

The ML control system can function to control the industrial facility, more preferably control the facility infrastructure (e.g., environment conditioning system, etc.) and or the control the IT infrastructure or components thereof (e.g., local cooling system, etc.). The ML control system preferably controls the facility by determining setpoints for the facility infrastructure components (e.g., chiller setpoints, air handling setpoints, local cooling setpoints, etc.), but can alternatively directly determine low-level control instructions, and/or otherwise control the facility.

As shown in FIG. 2, variants of the ML control system can include set of agents 300 (e.g. local agents 320, facility agents 310, etc.), a remote control plane 100, a client 200, data processing modules 400, an optional data store 500, a telemetry module 600, a learning module 700, and/or any other suitable components. The ML control system functions to control components of an industrial facility by predicting component setpoints (e.g., for environment conditioning system control, etc.).

All or portions of the ML control system can run or be executed locally (e.g., at the industrial system), remotely, in the cloud, be distributed, and/or have any other suitable deployment configuration. In a first variant, the ML control system can be fully airgapped within the local system. In a second variant, most of the ML control system is local, except supervisory control (e.g., can remotely monitor ML control system health and performance, etc.). In a third variant, all of the ML control system is local, but the configuration is set remotely. In a fourth variant, the client, data preparation modules (e.g., tagging module, processing module, feature extraction module, etc.), agent, and data store are local, while the remainder of the system is remote (e.g., example shown in FIG. 2). In a fourth variant, data diodes can be disposed between the ML control system and other control systems (e.g., load manager, etc.) to prevent data flow and/or data transmission between the ML control system and the other systems. In a specific example, the data diode may allow the ML control system to share data to the load manager but prevent data from the load manager to transmit to the ML control system. This specific example can have the benefit of ensuring the privacy of data sent to a facility by third parties. In a fifth variant, the ML control system can receive data from an out-of-band network through a data diode.

All or portions of the ML control system can be executed on: a CPU, GPU, microprocessor, ASIC, set thereof, any bare metal machine, and/or any other suitable execution platform. In an example, all or portions of the ML control system can be preloaded onto a chipset (e.g., supporting a set of GPUs, supporting a GPU rack, etc.).

The agent or plurality of agents can determine (e.g., predict, infer, interpolate, compute, calculate, etc.) setpoints for the environment conditioning system and/or any other suitable parameters. The agent can optionally determine the reward response by the environment (e.g., the industrial system's environment), generate state-action (e.g., setpoint-reward trajectories (e.g., associated with a state, action, and/or reward timestamp)), and/or any other suitable functions. The agent can send setpoints to the existing control system(s) (e.g., the building management system), wherein the existing control system(s) generate control instructions to meet the setpoints. The agent can determine setpoints on a predetermined interval (e.g., 15 min, 10 min, 1 min, 1 second, etc.) and/or any other suitable interval. The agent can be for a subsystem of the industrial system (e.g., only the environmental control system, only the liquid cooling system, etc.), but can alternatively be for all of the industrial system.

In variants, the agent can determine setpoints based on a set of inputs. The set of inputs can include supply temperatures (e.g., for the primary chiller loop, local cooling loop, secondary loop, CDU coolant loop, etc.), return temperatures (e.g., for the primary chiller loop, local cooling loop, secondary loop, CDU coolant loop, etc.), ambient temperatures, compute hardware temperatures, flow rates, differential pressures, and/or any other measurements. In variants, the set of inputs can include compute hardware performance limits and/or thresholds (e.g., throttling limits, T-limits), power consumption, voltage, current, amperage, and/or any other parameter.

In variants, the agent can determine setpoints and/or actions using a model (e.g., predictive models, decision models, models, control models, state approximators, etc.). In other variants, the agent can determine setpoints by optimizing an objective function (e.g., to minimize or maximize a target variable), but can alternatively be determined by directly predicting the setpoint values, and/or any other suitable determination method. In variants, the optimization can use a search to search for setpoint permutations that satisfy a set of predetermined constraints. In an example, search methods that can be used include: linear search, binary search, sequential search, exhaustive search, depth-first search, breadth-first search, grid search, random search, hill climbing, brute force search, branch and bound, and/or any other suitable search method.

In a first example, the agent can determine a set of setpoints that minimize environmental conditioning system power consumption. In a second example, the agent can determine a set of setpoints that maximize compute hardware computational output (e.g., enable the compute hardware to be overclocked, etc.). However, the agent can be used to optimize any suitable objective.

The agent is preferably based on the industrial facility state (e.g., system state), but can alternatively be based on other input and/or any other suitable basis. The industrial facility state preferably includes the current or future environment conditioning system state, alternatively and/or additionally includes the current and/or future compute hardware state (e.g., physical state, such as thermal load or power load, etc. ; digital state, such as job or process load, etc.), and/or any other suitable state parameters. The industrial facility state can include sensor streams, error codes, monitoring codes, and/or any other suitable state indicators. The agent preferably locally receives the industrial facility state (e.g., from a direct connection to the state source, from the building management system or LCS, etc.), but can alternatively receive the industrial facility state from a remote platform, wherein the remote platform receives the industrial facility state from the industrial facility and forwards it to the agent.

The agent is preferably a sequential decision-making agent (e.g., that iteratively determines the optimal setpoint permutation), but can alternatively be a direct prediction agent and/or any other suitable type of agent. The agent can be a trained machine learning model, but can alternatively be a regression, a regression-based neural network, or reinforcement learning model. The agent can include model predictive control, include a rule-based system, and/or be otherwise configured. In an example, machine learning models that can be used include: deep neural networks, model predictive control (MPC), linear quadratic regulators (LQR), proportional-integral-derivative (PID) controllers, fuzzy logic controllers, Gaussian processes, support vector machines (SVM), feed-forward neural network, random forests, gradient boosting machines, and hybrid combinations of classical control with learned components. The agent can be learned using reinforcement learning (e.g., generated by a learning agent) and/or any other suitable learning method. Examples of reinforcement learning algorithms can include policy gradient, proximal policy optimization (PPO), deep deterministic policy gradient, Q-learning, Monte Carlo policy gradient, or any other suitable algorithm.

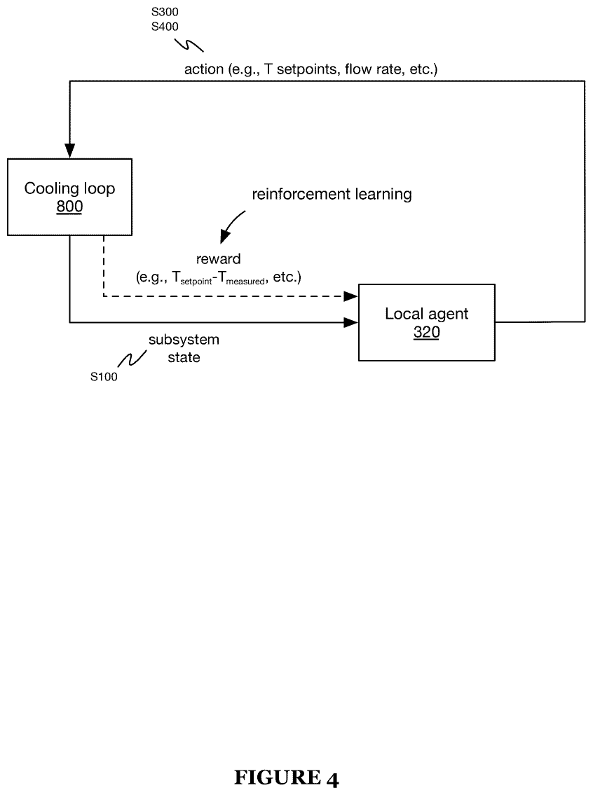

In variants, an agent can include a set of models and/or modules. For example, an agent can include a predictive model and/or state approximator, a decision model and/or action model, and/or other suitable model. In a specific example, the agent can predict a state of a system and/or a future state of a system (e.g., future thermal load, a thermal response, a future temperature, a power consumption, etc.) using an approximator, and determine setpoints based on the prediction using the decision model. In other variants, the agent can only include a decision module. In variants, the approximator and/or decision model can be independently trained and/or trained together (e.g. as a hybrid model). In variants, the coefficients, weights, and/or parameters of the models can be learned via reinforcement learning, as shown for example in FIG. 4.

In variants, the approximator (e.g., thermal response model, etc.) can include physics-based models (e.g. heat conduction models, convection models, lumped parameter thermal models, Newton's law of cooling, Stefan-Boltzmann law, heat equation, etc.), simulators, mathematical models, machine learning models (e.g., neural network, multilayer perceptron, convolutional neural network, recurrent neural network, etc.), statistical models (e.g., regression models, linear regression models, logistic regression models, Poisson regression models, time series models), probabilistic models, hybrid models, deterministic models, analytical models, and/or any suitable models.

In variants, the approximator can be trained to predict a future thermal load, thermal response, future temperature (e.g., compute hardware temperature, chiller fluid temperature, ambient temperature, etc.), a thermal latency and/or thermal response time, a power consumption, and/or any other suitable system state. In variants, the approximator can predict a global system state, average system state, and/or a local system state. For example, the approximator(s) can determine thermal responses and/or thermal loads for each component of a cooling loop (e.g., CDU, compute hardware, etc.).

In variants, the approximator can receive a system state (e.g., set of return temperatures, supply temperatures, compute hardware temperatures, chiller temperatures, flow rates, chiller temperatures, ambient temperatures, power consumption, etc.) as input and compute a future system state based on the system state. In variants, the input can include a time-series of system states. For example, the input to the approximator can include a set of temperatures from a previous set of time steps. The input can include one or more of: operational technology (OT) network information, out-of-band (OOB) IT network information, in-band IT network information, and/or other information.

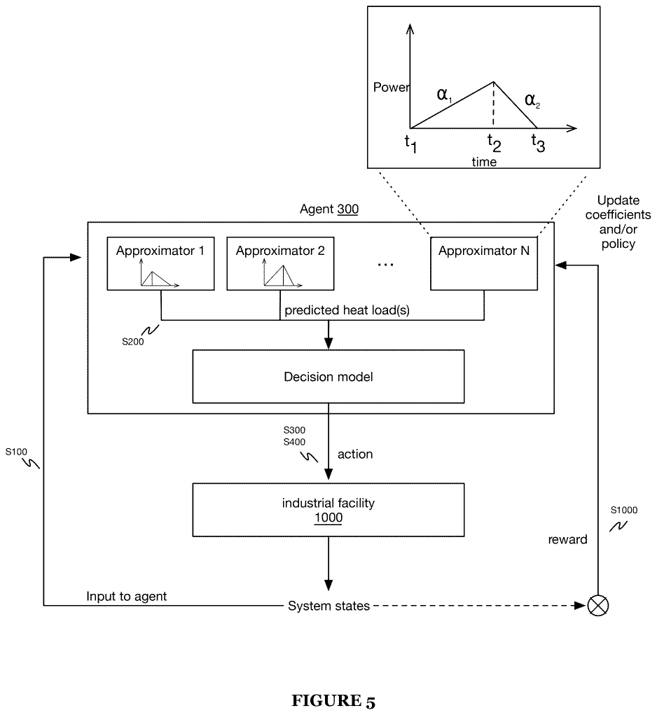

In a specific variant, the approximator can represents time-dependent responses (e.g. thermal load, heat, and/or power consumption) as triangular waveforms, parameterized by slopes, magnitude, temporal parameters, and/or any other suitable parameters (e.g., triangle model, etc.), as shown for example in FIG. 5. In examples, the triangle model can be defined by: a rising-slope coefficient (e.g., rate of heat accumulation or rate of power increase), a falling-slope coefficient (e.g., rate of heat dissipation or rate of power decrease), a peak-magnitude coefficient (e.g., maximum predicted thermal load or maximum power draw), and a temporal-extent coefficient (e.g., duration of the predicted event). These coefficients can collectively define the shape of the predicted triangular response, which can approximate accumulation and dissipation of heat and/or increases and decreases in power consumption.

The triangle model can be used to predict a future thermal load (e.g., by integrating the triangle waveform to define a total heat load, etc.). In variants, the triangle model receives as input a set of state variables associated with a specific technical loop (e.g., power signal, inlet temperature, outlet temperature, etc.) and outputs a predicted future thermal load and/or thermal response. For example, the model can compute a predicted heat-accumulation profile by integrating the triangular waveform (e.g., area under the triangle), which can represent a total future thermal load attributable to a predicted power spike or other transient event. In some variants, the model output (e.g., predicted thermal load) is used by the decision module to compute a supply-temperature setpoint for the corresponding cooling loop. For example, the decision module can preemptively lower a supply-temperature setpoint so that the available thermal transfer capacity of the loop approximates or exceeds the predicted load, such that the amount of cooling delivered (e.g., area-of-capacity, AOC) is maintained proportionally to the predicted thermal load represented by the triangular waveform.

In variants, the parameters of the triangle model can be learned or tuned during model training. For example, the triangle model coefficients can be adjusted and/or tuned using reinforcement learning techniques. In these variants, the training process can include: applying a setpoint determined using the predicted thermal load of the triangle model, measuring the resulting supply temperature actually achieved by the loop, and computing a reward signal based on the deviation between the model-determined setpoint and the measured supply temperature. The reward signal can be formulated to penalize deviations, such that the learning algorithm updates the triangle model coefficients to minimize the difference between predicted and actual supply temperatures over time. However, the reward signal can be any other metric.

Through iterative application, the model adapts to the thermal characteristics and affinities of individual CDUs or cooling loops, improving predictive accuracy and allowing the system to preemptively adjust supply temperatures to match anticipated thermal loads. Reinforcement learning can be applied locally per technical loop, enabling loop-specific tuning of triangle model parameters and respecting the independence of each control domain. However, in other variants the triangle model parameters can be determined during training (e.g., training using historical data), predetermined, or otherwise set.

In variants, the parameters of triangle models can describe system affinities. For instance in one triangle model for a specific CDU, the rising-slope coefficient may be higher than that in other models in response to observed correlations between power spikes and rapid temperature increases, while the falling-slope coefficient may adapt to component-specific or loop-specific cooldown characteristics. In these variants, the relationships learned by the model can capture affinities (e.g., sensitivities or coupling strengths between power consumption and thermal behavior, between slope changes and corresponding temperature responses, etc.). Affinities can be encoded implicitly in the learned coefficients; for instance, a steeper rising-slope coefficient may represent a high affinity between power consumption and heat generation for a specific CDU or rack group, while a longer temporal-extent coefficient may represent slower thermal recovery for that loop.

In a second specific variant, the approximator can be a physics-based model. In this variant, the model can include a set of physics-based equations used to compute a future temperature, heat, pressure, and/or any other value. In examples of the second specific variant, equations can include heat transfer equations (e.g., Fourier's law of heat conduction, convective heat transfer equations), fluid dynamics equations (e.g., Navier-Stokes equations), energy balance equations, and thermodynamic relations (e.g., ideal gas law, conservation of energy equations), or any other suitable physics-based equations.

In another specific variant, the approximator can be a machine learning model where the model is trained to determine a future system based on system state inputs. In variants, the machine learning model can include linear layers, convolution layers, max pool layers, attention mechanisms, recurrent layers, normalization layers, activation functions, dropout layers, residual connections, embedding layers, graph convolutional layers, transformer blocks, generative layers, and/or any other suitable machine learning model layer and/or module.

In variants, the ML control system can include multiple state approximators. For example, a state approximator can be determined for every component (e.g., CDU, compute hardware instance, etc.), cooling loop, technical loop, rack, aisle, zone, device, room, and/or any other system and/or subsystem. In this variant, each model can be trained separately, trained using different data, or otherwise trained. In an example, the system can include a different model (e.g., state approximator) for each CDU, wherein each model is learned based on the operation parameters (e.g., power spikes, response curves, etc.) of the respective CDU. In a specific variant, the ML control system can include one state approximator for every CDU. However, the ML control system can have any suitable amount of state approximators.

However, the approximator can be any suitable model.

In variants, a decision and/or action model can include a model, a set of heuristics, rules, and/or policies, a solver and/or search module used for optimization, a look-up table, a numerical mapping and/or mathematical function, and/or any suitable method. The models can include a machine learning model (e.g., neural network, multilayer perceptron model, convolutional neural network, recurrent neural network, etc.), a physics-based model, a statistical model (e.g., linear regression, logistic regression, Poisson regression, time series model, etc.), a probabilistic model, a hybrid model, and/or any other model.

In a first variant, the decision model can include a model that can receive, as input, system states, predicted future system states (e.g., determined from the predictive model and/or state approximator), and/or system properties and/or constraints, and determine (e.g., compute, calculate, predict, select, etc.) setpoints based off the input. In an example, the system state, predicted system states, and system properties, can be passed through the decision model. The decision model can then produce, as output, a set of setpoints. As a specific example, when multiple CDUs are present, each CDU can be associated with its own approximator that predicts a CDU-specific thermal load. The decision model can receive the set of predicted thermal loads and for each CDU, apply a mapping, neural operator, physics-based model, or any other suitable model relating heat and temperature to compute each CDU's setpoint.

In a second variant, the decision model can include a set of heuristics, rules, and/or policies. The decision model can include learned and/or predetermined rules and/or policies. In an example, a rule and/or policy can include reducing and/or increasing a setpoint (e.g., temperature, flow rate, pressure, fan speed, etc.) when a system state and/or predicted future system state is determined. As a specific example, when a state approximator predicts a thermal response and/or heat load, the decision model can apply a heuristic rule such as lowering a setpoint by a predetermined value when a heat load exceeds a threshold. In this manner, the decision model can use simple rule-based logic to translate predicted heat dynamics from the approximator into actionable setpoint changes for the specific CDU associated with those predictions. However, the method can include using any other suitable rules and/or heuristics. In variants, these rules, heuristics, and/or policies can be manually determined (e.g., using domain knowledge), learned (e.g., through reinforcement learning, policy gradient methods, proximal policy optimization, etc.), and/or otherwise established.

In a third variant, the decision model can include a solver and/or search algorithm. In this variant, the decision model can determine setpoints by finding an exact solution to an optimization problem, an optimal solution to an optimization, a sub-optimal solution to the optimization problem, a possible solution to the optimization, and/or any other possible solution. This solution can be determined through a search process (e.g., exhaustive search, branch-and-bound search, etc.), by mathematically solving the optimization problem (e.g. solving a system of equation), by applying a numerical optimization technique (e.g., gradient descent, convex optimization, stochastic optimization, or evolutionary optimization), by employing an approximation or relaxation of the optimization problem, by performing probabilistic inference (e.g., variational inference or Bayesian optimization), or otherwise solved.

In a variant, the decision model can operate directly on the predicted thermal response generated by the approximator (e.g., the triangle model). The triangle model produces a parametric prediction of heat accumulation (e.g., via rise slope, fall slope, magnitude, and duration coefficients), which is integrated into a predicted thermal load. The decision model then applies a deterministic, learned mapping, and/or mathematical function between predicted heat load and the resulting supply temperature setpoint, such that setpoint is proactively lowered in proportion to the anticipated heat. In reinforcement-learning variants, this mapping is learned, with the reward defined by deviation between model-derived setpoints and measured supply temperature, along with penalties for thermal excursions, actuator limits, or inefficiency.

However, the decision model can be otherwise configured.

The agent can have a set of operation modes. Examples of operation modes can include a normal operating mode, a safe mode, a reduced-functionality mode, a fallback mode, a fault-responsive mode, and/or any other suitable modes. The operation mode can be selected manually, automatically, in-response to a trigger (e.g., anomaly detection, operational error detection, sensor measurement exceeding a threshold, etc.), and/or in any suitable manner. In variants, the agent can operate in a fault-responsive mode when abnormal behavior is determined. Examples of abnormal behavior can include: data and/or information ceasing to send, data and/or information degrading, temperatures (e.g., secondary supply temperatures, primary supply temperatures, return temperatures, etc.) rising beyond an acceptable margin, mechanical issues (e.g., pump failure, valve sticks, etc.), and/or any other abnormal conditions. In variants, depending on these conditions, the agent can dynamically change its behavior to address the changing expected responses. The agent's operation mode can be determined based on sensor data, system states, predicted system states (e.g., from the approximator, etc.), model outputs and/or encodings, predefined rules and/or heuristics (e.g., mapping the abnormal behavior to a set of default behaviors, mapping abnormal values to a set of default setpoints, etc.), and/or any other suitable information. The operation mode can be independent across agents (e.g., different agents can have different selected operation modes at a time, etc.), systems, subsystems, and/or otherwise controlled. Depending on the operation mode, the agent can alter its operations. Examples of operational modifications can include: selecting and/or utilizing different models (e.g., different approximators and/or decision models, etc.), adjusting model parameters and/or constraints, modifying optimization or control objectives, limiting or disabling certain functions, transitioning from adaptive or data-driven behavior to deterministic and/or rule-based behavior, or any other changes in operation. In some modes, outputs (e.g., setpoints, predictions, etc.) generated by different models and/or agents can be prioritized (e.g., such that a generated setpoint is ignored, replaced, bounded, etc). For example, a safe mode and/or fault-responsive mode can cause the agent to utilize previously determined setpoints, default setpoints, minimum allowed setpoints, setpoints determined from a different control system (e.g., PID), and/or any other setpoint.

In some variants, such as when the primary supply temperature rises beyond a margin or there is an issue with the CDU, the agent can lower the base setpoint below a typical default value. In these and other situations, the CDU may not be able to sufficiently cool the system when on full utilization due to the incident occurring out of scope of the local agent. Running at a lower temperature setpoint can enable the cooling system to cool more aggressively, preventing or limiting impacts of the unfavorable conditions. In other variants, changes in the dynamics of the facility and/or cooling systems can be detected. Examples of changes can include initiation of a large training job, large thermal and/or power draw spikes, a rack in the pod is disconnected, or any other system change. In these variants, the agent's model can tune its weights to manage the change in dynamics. This mode change could be learned, manually triggered, or deterministically set based on the change in conditions and whether or not our response is less favorable. The possible change in behavior can be broad, including changing the type of model, the type of tuner, the target setpoint, allowed setpoint bands, and/or any other agent parameters.

In variants, the agent can optionally be operable between an exploit versus explore mode, wherein the mode can be automatically determined, specified by the remote computing system, etc. The agent can alternatively only be operable in an exploit mode.

The agent preferably executes locally on-premises (e.g., on a local computing system within the industrial facility), but can alternatively execute remotely. The local computing system can be the same as that running the building management system, but can alternatively be a different machine.

The agent can run on a predetermined, controlled computing environment (e.g., virtual machine, container, etc.) and/or any other suitable computing environment. For example, the agent can be designed to run on a virtual machine (VM) on the customer side, and/or can be integrated directly into hardware ports as part of their local controller setup.

The agent is can be located on the client side or external side of the firewall (e.g., wherein the BMS treats the agent as a third party system, etc.), but can alternatively be located on the BMS side or the internal side of the firewall (e.g., wherein new versions of the agent can be deployed manually, after testing, etc.) or deployed on any suitable network (e.g., OOB IT network, etc.).

In variants, the agent can be deployed as a single binary or Docker container that packages together the data normalization component and the agent itself. The agent can alternatively be deployed as multiple images using Docker compose.

In variants where signed software requirements exist, the deployment process can include signing the binaries, installers, code, configuration, and/or other software components before installation on the customer's system. In these variants, one piece of software (e.g., the code) can verify the signature of the dependencies that it is relying upon (e.g., the configuration, etc.). However, the signatures can be otherwise used.

The agent can operate according to a specification. The specification can specify what information is provided by the agent to the remote computing system, default settings for the agent, how the agent should interact with the remote computing system, and/or any other suitable specifications. The version of the specification to use can be selected by a user, automatically selected, and/or any other suitable selection method. In an example, a first version of the specification sends heartbeats back to the remote computing system, while a second version of the specification adds read-only capabilities, auto reenablement features, and/or any other suitable features.

The agent can be static (e.g., not updated), updated (e.g., wherein the remote computing system can send new versions of the agent to the local system), learned online, and/or otherwise configured.

In variants, new agents (e.g., new model weights, parameters, etc.) can be compiled into a binary, which can optionally be signed (e.g., by a trusted key issued by the industrial facility, issued by a third party, etc.), and deployed to the local system.

In variants, the local system can store multiple versions of the agents to enable quick rollbacks (e.g., controlled through flags sent from the remote computing system).

In variants, the ML control system and/or components thereof (e.g., agents) can be secured and/or validated using: software signing for installers and executables deployed to customer network; a trusted member of the customer team can validate new configurations and model binaries before deployment; using data diodes that enables one-way egress of data while preventing inbound connections; a split system architecture that runs minimal trusted code near sensitive control systems while keeping larger components in less restricted zones; updating models and configurations through signed packages validated by the customer or through cloud-based control flags, and/or any other suitable security methods.

In an example, the agent package or binary can include a cryptographic signature (e.g., generated by a cryptographic key that is trusted by the industrial facility, etc.).

In specific variants, the ML control system preferably includes a set of agents (e.g., reinforcement learning agents), but can alternatively include a rule set, a set of model predictive control controllers, and/or any other suitable control system implementation.

In variants, the ML control system can include one or more agents. Each agent can be: a regression-based neural network, convolutional neural network (CNN), deep neural network (DNN), a regression, a statistical model, a deterministic model, a rule-based model, an analytical model, and/or have any other model architecture. The different agents in the ML control system preferably have the same model architecture, but can alternatively have different model architectures. The ML control system can include different agents of different types. The different agents preferably have different objective functions, but can alternatively have the same objective function. The different agents in the ML control system can be independently learned (e.g., using its own reinforcement learning loop), or alternatively learned together (e.g., holistically), and/or otherwise learned.

In variants, the agents 300 can include facility agents 310; local cooling agents 320 (e.g., CDU agents); and/or any other suitable components.

The facility agent can function as a supervisory controller for the facility infrastructure. The facility agent can determine setpoints for the facility infrastructure (facility setpoints). The facility setpoints preferably cause facility infrastructure to provide sufficient cooling ability for current IT infrastructure thermal load, and/or proactively adjust thermal transfer capacity based on predicted loads (e.g., from power demand data, job scheduling information), but can alternatively determine setpoints based on other suitable parameters.

In an example, the facility agent can determine chiller setpoints (e.g., start stop command, leaving fluid temperature, etc.), air cooling setpoints (e.g., fan speed, etc.), and/or any other suitable setpoints.

The facility agent preferably runs at a first frequency (e.g., low frequency, every 15 mins, etc.), but can alternatively run at a higher frequency and/or any other suitable frequency. The facility setpoints are preferably determined based on the facility infrastructure state (e.g., from the facility infrastructure subsystems, etc.), wherein the facility infrastructure state is influenced by but does not explicitly include the local cooling systems state (e.g., since the local cooling systems provide waste heat to the facility infrastructure).

The facility setpoints can alternatively be determined based on the explicit local cooling system states (e.g., communicated by the local cooling agents, by the CDUs, etc.). The local cooling system state can include: valve position, leaving water temperature, setpoints generated by the local cooling agents, and/or any other suitable state parameters. The facility setpoints preferably do not include local cooling system setpoints, but can alternatively include local cooling system setpoints.

The facility setpoints can additionally or alternatively be determined based on power demand, job scheduling information (e.g., queue size, job schedule, etc.), and/or other leading indicators, wherein the facility agent can predict the future thermal load based on the leading indicators and set the setpoints based on the predictions. The facility setpoints can additionally or alternatively be determined based on weather and/or any other suitable factors.

The facility agent preferably provides facility setpoints to the facility control systems (e.g., wherein the facility control systems control the facility components to meet the facility setpoints), but can optionally provide the facility setpoints to the local cooling agents, and can alternatively not provide the facility setpoints.

In a first variant, the facility agent determines setpoints for the facility subsystems (e.g., chiller, air handling system, etc.) based on state information from the respective facility subsystems. In this variant, the facility agent can receive indirect physical feedback from the compute hardware (e.g., from temperature changes, power draw, etc.), but does not receive explicit data feedback from the compute hardware.

In a second variant, the facility agent determines setpoints for the facility subsystems based on state information from the respective facility subsystems and the machine groups (e.g., valve positions, etc.). The machine group state information can be used as input variables in the optimization, or otherwise used.

The facility agent preferably determines the setpoints by optimizing an objective function, but can alternatively determine the setpoints by predicting the setpoints, and/or any other suitable determination method. In examples, the facility agent can estimate an internal state of the facility; roll out the power, thermal, or other physical trajectory over the internal state (e.g., using dynamic modeling); and determine a set of setpoints that optimize a target variable (e.g., power) over that trajectory. However, the facility agent can otherwise determine setpoints that optimize the power over a timeframe.

The objective function preferably includes: power as a function of the state inputs and setpoint values, but can be otherwise defined. The optimization preferably searches for the setpoint value permutation that optimizes the power value (e.g., minimizes the power value) while satisfying a set of constraints, but can alternatively predict the setpoint value permutations, and/or any other suitable optimization method.

In examples, the target value for the setpoint value permutation can be determined by estimating an internal state (e.g., based on the setpoint permutation) and rolling out the power, thermal, or other physical trajectory over the internal state, but can alternatively be otherwise determined. The setpoint value permutation can be identified using: branch & bound, simulated annealing, genetic algorithms, greedy algorithms, and/or any other suitable algorithms.

The constraints are preferably set by the facility operator, but can alternatively be set based on the predicted thermal demand (e.g., predicted from the power demand, job scheduling information, etc.). In an example, power demand, job scheduling information, and/or other leading indicators are used to predict the future thermal demand, wherein the future thermal demand is used as a minimum constraint on the optimization. In a specific example, facility setpoint values can be determined by dynamically modeling the thermal response and integrating the thermal load over time to determine minimum cooling capacity requirements.

The optimization can also incorporate predictive factors like upcoming job loads and weather conditions to proactively adjust setpoints while maintaining system stability.

In a first example, facility setpoint values can be determined by optimizing an objective function using a regression-based neural network trained on historical operational data. In a second example, facility setpoint values can be determined by dynamically modeling the thermal response (e.g., using the approximator, etc.) and integrating the heat load over time to determine minimum cooling capacity requirements. In a third example, facility setpoint values can be determined by using a constraint-based optimization where power usage data and/or job scheduling information provide bounds on required cooling capacity which then constrain the allowable setpoint ranges.

However, the facility setpoint values can be otherwise determined.

The facility agent can be learned by controlling the facility based on the setpoints; determining the facility response (e.g., from the facility state); generating a reward based on the facility response; and learning off the setpoint-reward pair. The facility agent can alternatively be trained using supervised learning using a setpoint-response pair. The facility agent can alternatively be otherwise generated.

The system preferably includes a single facility agent, but can alternatively include different facility agents for different facility infrastructure subsystems or instances thereof.

The facility agent can function as a supervisory controller that monitors system states and manages operational parameters. In an example, the facility agent (e.g., chilled water plant agent) can act as a supervisory controller that monitors the overall cooling system state. The facility agent can receive state information (e.g., valve positions, leaving water temperatures) from individual CDU agents and air handler units.

The facility agent can aggregate data from multiple sources along with leading indicators like power consumption to maintain sufficient cooling capacity. The facility agent can function as an enabler for the CDUs by providing the necessary chilled water capacity and temperature/pressure setpoints to the primary cooling loop, rather than directly controlling the CDU setpoints.

The facility agent can proactively adjust capacity based on predicted loads from power data and/or any other suitable data sources. In variants, the facility agent can utilize job scheduling information for capacity adjustment and/or any other suitable operational parameters.

However, the facility agent may be otherwise configured.

The local cooling agent can function to determine local setpoints for a given local cooling system (e.g., for a CDU, for a liquid cooling system, etc.). In an example, the local cooling agent can be a CDU agent, configured to generate setpoints for CDU control. In a variant a local cooling agent can be a cooling loop agent, configured to generate setpoints for every CDU in the cooling loop. In these variants, ML control systems can include a plurality of local cooling agents (e.g., one agent for every cooling loop or CDU, etc.). The local cooling agent preferably provides local setpoints to the CDUs (e.g., to standard endpoints within the CDUs), wherein the CDUs control the local cooling system to meet the local setpoints, and/or any other suitable control parameters. The local setpoints can include: the differential pressure for the coolant loop, volumetric flow rate, mass flow rate, flow coefficient (e.g., via valve control, etc.), the supply temperature for the coolant, and/or any other suitable setpoints.

The local cooling agent preferably runs at a second frequency (e.g., high frequency, every 1 min, etc.) different from the facility agent(s), but can alternatively run at a higher frequency or lower frequency than the facility agent(s), and/or at any other suitable frequency.

The local setpoints are preferably determined based on the local cooling system state (e.g., physical state, job schedule, etc.), but can additionally or alternatively be determined based on the pod or rack operation information (e.g., power consumption, thermal load, current jobs, scheduled jobs, etc.), facility-level information (e.g., facility setpoints, etc.), and/or other data. In a specific example, the local setpoints can be determined based on a measured supply and/or return temperature of coolant, temperatures of coolant at the inlet and outlet of a CDU, a compute hardware temperature, an ambient temperature, an outside temperature, constraints of the compute hardware (e.g., throttling limits, temperature limits, clocking speeds and/or thresholds, etc.) and/or any other physical state parameter, sensor measurement, property, and/or constraint.

The local setpoints can additionally or alternatively be determined based on the facility setpoints. The facility setpoints are preferably used as constraints on the local cooling agent optimization, but can alternatively be used as input variables or otherwise used. Alternatively, projected resource availability (e.g., power capacity, thermal capacity, thermal transfer capacity, etc.) can be determined from the facility setpoints (e.g., predicted by the facility agent, etc.), wherein the projected resource availability can be used as constraints on the local cooling agent optimization. For example, each local cooling agent can only select setpoints that keep its projected resource consumption within 1/N of the projected overall resource availability (e.g., in a system with N pods). In another example, the facility setpoints can include resource envelope allocations for each local cooling agent, wherein the local cooling agent can only select setpoints that keep the projected resource consumption within the allocated resource envelope. However, the local cooling agent can otherwise be constrained by the facility setpoints.

In a first variant, the local cooling agent determines CDU setpoints using the local cooling system state, without explicit knowledge of the facility setpoints. Alternatively and/or additionally, the local cooling agent determines CDU setpoints using the state of a subsystem of the local cooling system (e.g., a cooling loop) without explicit knowledge of the facility setpoints or the state of other subsystems.

In a second variant, the local cooling agent determines CDU setpoints using the local cooling system state and the facility setpoints, wherein the facility setpoints can be used as input variables (e.g., independent variables) in the objective function. In variants, facility setpoints can include setpoints for the IT infrastructure, facility infrastructure, or any other component, system, and/or subsystem. For example, CDU setpoints can be determined based on an ambient temperature setpoint of the facility and/or a compute hardware's core utilization percentage.

In a third variant, the local cooling agent determines CDU setpoints using the local cooling system state and the overall facility resource availability, wherein the overall facility resource availability is determined (e.g., calculated) from the facility setpoints, wherein the overall facility resource availability is used as a global constraint on the set of local cooling agents. In this variant, the local cooling agent can coordinate with other local cooling agents to ensure that the collective local setpoints determined by the set of local cooling agents does not exceed the overall facility resource availability (e.g., by tracking the minimum bounds of the other local cooling agents when performing the setpoint value search during the optimization).

In a fourth variant, the local cooling agent determines CDU setpoints using the local cooling system state and a facility resource envelope allocated to the local cooling agent (and/or machine group) by the facility agent, wherein the facility resource envelope (e.g., cooling allocation, power allocation, etc.) is used as a constraint on the local cooling agent's setpoint optimization.

In a fifth variant, the local cooling agent determines CDU setpoints based on facility errors and/or abnormal operations information (e.g., determined from sensor measurements, telemetry module, monitoring system, etc.). In these variants, the determined setpoints can allow the facility to safely operate outside of typical and/or trained regimes.

In specific variants, the local setpoints can be determined based on the compute hardware. For example, a compute hardware's setpoint, metric, and/or constraint can be used as an input variable to determine a local setpoint. For example, a local setpoint can be determined based on a compute hardware's power consumption, workload intensity, dynamic voltage and frequency scaling state, clocking frequency, core voltage, core utilization, memory utilization, fan speed, performance state, thermal limit (e.g. T-limit), thermal headroom (e.g., before performance drop, degradation, throttling, etc.), age, degradation level, and/or any suitable metric. For example, a local cooling agent can determine that a CDU connected to a compute hardware running with higher clocking frequencies (e.g. overclocking) should run coolant at a faster flow rate.

In specific variants, the local setpoint can be determined based on predicted system states and/or metrics. For example, a local cooling agent can predict a future thermal load, temperature, power consumption, thermal response, and/or any other state, and determine a setpoint based on the prediction. In variants, a local agent can determine a set of predictions. For example, a local agent can predict a plurality of types of metrics for a cooling loop, a metric for each CDU in a cooling loop, a plurality of metrics for each CDU in a cooling loop, a metric for each compute hardware, and/or any suitable metrics. In a specific variant, a local cooling agent can predict a thermal load for every CDU of a cooling loop and determine setpoints based on the predicted thermal responses. However, any parameter and/state can be predicted for a CDU or component of a subsystem. In variants, the same model or different models can be used to determine the prediction across the CDUs. In a variant, the predictive models can have the same architecture but can have different coefficients, weights, and/or any other parameter. Having a plurality of local cooling agents, each with different predictive models for the components within the associated subsystem (e.g., cooling loop) can have the benefit of accurately handling and/or controlling subsystems with diverse and/or heterogeneous component behavior (e.g., thermal response, etc.). For example, a local cooling agent can learn and refine distinct affinities between CDUs, compute hardware, and the cooling loop infrastructure (e.g., power draw vs. thermal load, pump speed vs. flow response) defined by the plurality of models. Such learned affinities can enable the agent to more accurately tailor setpoints to the unique interactions and dependencies present in the industrial facility.

However, the local cooling agent can otherwise determine the CDU setpoints (local setpoints).

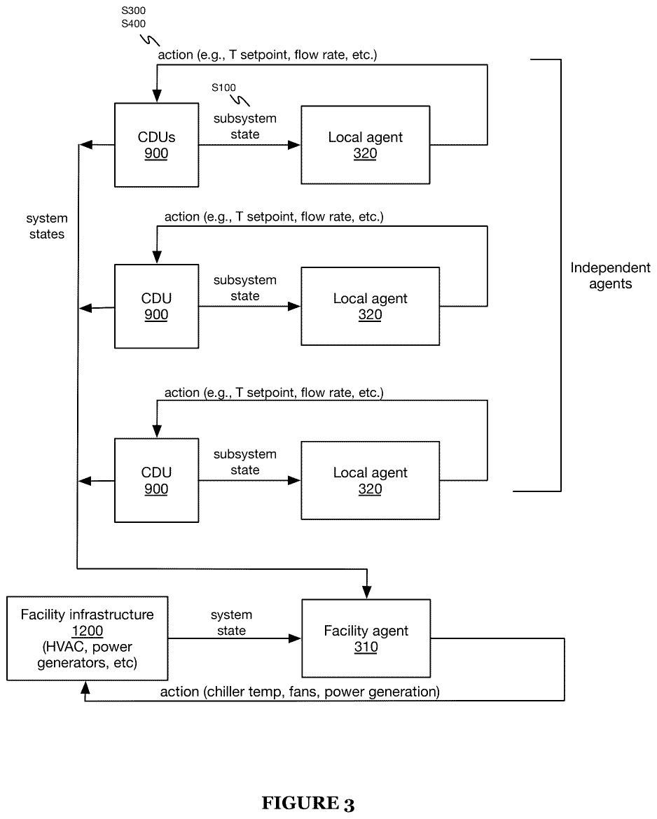

The ML control system can include one or more local cooling agents (e.g., 1 per CDU, etc.), and/or any other suitable number of local cooling agents. In variants, the local cooling agents can be communicatively connected such that information and/or data can be shared between the agents. Communicative connection can have the benefit of global optimization and coordinated operations and control. In other variants, the local cooling agents do not interact. For example, a local cooling agent associated with a cooling loop and/or subsystem (e.g., CDU, set of CDUs, and/or any other component or set of components) can determine setpoints based only on its local system and not other subsystems and/or cooling loops of the industrial facility, as shown for example in FIG. 3. In some variants, each local agent can be configured to not receive the system states of other subsystems. Independent local cooling agents can have the benefit of highly optimized subsystems that can handle inconsistent workloads across the industrial facility and heterogeneous thermal responses, while having increased modularity and tunability. For example, independent and distinct local agents can result in a tailored control system that accounts for diverse facility infrastructure. Additionally, by limiting each control agent to only optimizing a subproblem of the overall facility optimization, system control can be faster, more efficient, and more responsive.

The local cooling agent preferably determines the local setpoints by optimizing an objective function, but can alternatively determine the local setpoints by predicting the local setpoints, and/or any other suitable determination method. The objective function is preferably power as a function of the state inputs and/or setpoint values, but can alternatively be the number of jobs or cost as a function of the state inputs and/or setpoint values, or otherwise defined. The objective function is preferably different from the facility agent's objective function, but can alternatively be the same.

The optimization can iteratively search for setpoint value permutations that optimize the target variable (e.g., power, number of jobs, cost, etc.) given a set of constraints. In examples, the target value for the setpoint value permutation can be determined by estimating an internal state (e.g., based on the setpoint permutation) and rolling out the power, thermal, or other physical trajectory over the internal state (e.g., using dynamics modelling), but can alternatively be otherwise determined. The setpoint value permutation can be identified using: branch & bound, simulated annealing, genetic algorithms, greedy algorithms, and/or any other suitable methods. The constraints can constrain the search space (e.g., the setpoint values that are permitted).

In a first variant, the constraints are default constraints (e.g., a set of rules). In an example, the constraints only allow actions that provide more cooling. The rules can be extracted from historical data (e.g., power spikes) or otherwise determined.

In a second variant, the constraints include maximum power and/or thermal load allocated to the machine group, determined based on the facility setpoints (e.g., current facility setpoints, future setpoints etc.). In an example, only local setpoints that result in resource consumption (e.g., power consumption, thermal load, etc.) within a resource budget, determined based on the facility setpoints, are permitted. The resource budget can be determined by the local cooling agent, by the facility agent (e.g., assigned to the local cooling agent, etc.). In an example, the resource budget can be 1/N of the overall resource budget, wherein the facility includes N local cooling agents.

In a third variant, the constraints include minimum cooling capacity requirement from the controlled machines. The minimum power and/or thermal load can be predicted by a learned dynamics model (e.g., based on the controlled machine's current states, predicted power spikes, job information, etc.), but can alternatively be otherwise determined.

However, the local cooling agent may be otherwise configured.

The ML control system is preferably separate from the existing control systems, but can alternatively be bundled into the existing control systems of the industrial facility.

The local portions of the ML control system can be deployed as: binaries, images, containers, virtual machine templates, configuration management scripts (e.g., Ansible/Chef/Puppet), serverless functions, helm charts for Kubernetes, system packages (RPM/DEB), embedded firmware images, WebAssembly modules, platform-specific installers (MSI/PKG), and/or any other suitable deployment formats.

In variants, the ML control system modules (e.g., agents, models, approximators, decision and/or model, etc.) can be encrypted, unencrypted, or otherwise configured. In variants, components of the ML control system can be out-of-band (e.g., from the operational technology and/or information technology networks). In variants, utilizing out-of-band (e.g., OOB) networks for the agents allows easier interfacing between the agents and the compute hardware.

In variants, the in-band (IB) IT network can be an information-technology network that communicates with the computation hardware through the same communication pathways used for user/application traffic. For example, the in-band IT network can include the internal server network interfaces, top-of-rack (ToR) switches, or other data paths used by the computing devices. Information obtained via the in-band IT network can include device-reported telemetry such as CPU utilization, rack-level and/or server-level power consumption, power-related telemetry, workload metadata, component temperatures reported through system management interfaces (e.g., via IPMI-over-LAN, Redfish over HTTP), or any other operational metrics available through host-side software. In some variants, the system can use the rack-level power measurement obtained via the in-band IT network as part of determining the system state.

In variants, the out-of-band (OOB) IT network can be a logically or physically separate management network that provides access to platform management controllers of the computing devices. For example, the out-of-band IT network can include baseboard management controllers (BMCs), chassis management controllers, or remote management interfaces (e.g., IPMI, Redfish, iLO, iDRAC). Information obtained via the out-of-band IT network can include inlet temperature, outlet temperature, board level thermal sensor readings, power telemetry, fan speed, component health indicators, or any other management-level metrics exposed by the platform hardware. In some variants, rack-level power telemetry obtained from BMCs or other management controllers can be used when determining the system state.

In variants, the operational technology (OT) network can be an operational-technology network that connects facility-level equipment, such as cooling system components and environmental sensors. For example, the OT network can include industrial fieldbuses, programmable logic controllers (PLCs), supervisory control and data acquisition (SCADA) systems, building-management systems (BMS), and/or any other infrastructure-level control networks. Information obtained via the OT network can include temperatures (e.g., supply temperature, return temperature), flow rates, pressures, pump speeds, valve positions, chiller setpoints, facility power measurements, and/or any other infrastructure telemetry. In variants, the OT network provides the primary sensor data for determining cooling-loop conditions (e.g., supply/return temperatures and flow rates).

In variants, information and/or data from the OOB IT network, IB IT network, OT network, and/or any other network, can be received, processed, and/or otherwise utilized, by the ML control system. In variants, the agent can receive data from one network or a plurality of networks.

Different local components can be sent as individual binaries or as a unified binary. Different binaries can be bundled into a single image, but can alternatively be bundled into different images.

Examples of the architecture allows for different security configurations the binaries can either sit fully on the client side outside the firewall, or be split with components sitting closer to the LCS in their trusted zone. A data diode approach can be used for one-way data flow to the client side and/or the remote computing system. In variants, updates to binaries on the local side of the firewall can require validation by trusted customer personnel before deployment.

The remote control plane can provide unified management from the cloud, wherein the management can include model updates, configuration changes, version control of the on-premise agents, and/or any other suitable management functions. The remote control plane can preferably execute on a remote computing system (e.g., remote from the industrial facility, etc.), but can alternatively execute on any other suitable computing system. The remote control plane can provide heartbeat to the local ML control system components, wherein the local ML control system components can shut down or default to a default operation mode when a heartbeat is not received. The remote control plane can provide mechanisms to send various flags to the local agents, such as selecting which versions of models to use, which mode to operate within (e.g., explore vs. exploit, etc.), and/or any other suitable flags. The remote control plane can enable quick rollbacks when needed. The remote control plane can handle monitoring, management, data processing, training, and/or any other suitable functions while maintaining supervisory control over the distributed on-premise agents. However, the remote control plane may be otherwise configured.

The client can function as an interface between the agent and one or more of the existing control systems. The client can facilitate communication, data transfer, and/or any other suitable interface functions between the agent and the existing control systems. The client can receive setpoints from the agent and pass the setpoints to the existing control systems (e.g., building management system) and/or any other suitable control systems. The client can be local to the industrial system and/or any other suitable location relative to the industrial system. The client can manage version control. In an example, the client can dynamically select the specification or agent version to receive setpoints from or run, based on the specification identifier or version identifier received from the remote computing system (e.g., supervisory layer). The client can provide a static interface with the control system, which enables the agent to be dynamically updated without changing the existing control system. The client can manage data transfer. In an example, the client can provide industrial system data from the existing control system to the agent and/or any other suitable data transfer functions. The client can verify communications received from an external system using cryptographic techniques, including symmetric or asymmetric cryptography. For example, the client can authenticate and/or secure communications using transport-layer security (TLS), mutual TLS (mTLS), and/or separate cryptographic signing or encryption mechanisms. However, the client may be otherwise configured.

The data processing modules can function to process data for the agent and/or for the learning module. The data processing modules can process any other suitable data and/or process data for any other suitable purpose. The data processing modules can be run locally, remotely, and/or in any other suitable location. All or a subset of the data processing modules can be run locally, remotely, and/or in any other suitable location.

The data processing modules can include a tagging module, a data normalization module, a feature extractor and/or any other suitable components.

The tagging module can function to tag the data streams with a unified ontology and/or any other suitable tagging functionality. The tagging module can utilize a unified ontology that can be: learned, received from the remote computing system, and/or any other suitable method of obtaining the unified ontology. The tagged data from the tagging module can be used for: feature extraction (e.g., predetermined feature extraction modules are applied to data streams with a predetermined tag, etc.), training, inference, and/or any other suitable purposes.

In a first variant, the tagging module executes locally, wherein the tagging module tags the data as it is received by the local system. The data transmitted to the remote computing system can be tagged or raw.

In a second variant, the tagging module executes remotely, wherein the raw data is transmitted to the remote computing system, wherein the tagging module in the remote computing system tags the data. The tagged data can optionally be sent back to the local agent.

However, the tagging module may be otherwise configured.

The data normalization module can normalize the industrial system data. The data normalization module can normalize the industrial system data using one or more normalization techniques and/or any other suitable data processing methods. The data normalization module can normalize tagged data, raw data, and/or any other suitable data types. The data normalization module can normalize data, wherein features are preferably extracted from the normalized data, but can alternatively be extracted from raw data and/or any other suitable data source. The data normalization module can perform various data normalization operations. In an example, data normalization can include: scaling raw sensor data from multiple pods, feature computation and transformation of tag data into standardized formats, compressing high frequency time-series data before transmission, batching/aggregating data streams for efficient processing, and/or any other suitable data normalization operations. However, the data normalization module may be otherwise configured.

The feature extractor can extract features for inference (e.g., for agent ingestion) and/or any other suitable purposes. The feature extractor can be specific to a combination of tags, can alternatively be specific to a data stream, and/or any other suitable specification type. The feature extractor can extract features including: handcrafted features (e.g., numerical features, statistical features, etc.), learned features, eigenfeatures (e.g., PDA, LDA, ICA, etc.), and/or any other suitable features. However, the feature extractor may be otherwise configured.

However, the data processing modules may be otherwise configured.

The optional data store can function to store historical data for stateful agent computations and/or any other suitable data storage functions. In examples, data that can be stored can include: raw data, tagged data, model features, the industrial system state, commanded setpoints, predicted industrial system response, and/or any other suitable data types. The data store can store data that can be used by the agent (e.g., for stateful computations during inference), and/or any other suitable use. The data store can be stored: locally (e.g., on the same computing system as the agent, etc.), remotely (e.g., at the remote computing system), and/or any other suitable storage location. The data store can be a cache, buffer, and/or any other suitable data storage mechanism. The data store can preferably temporarily store the data (e.g., as long as the agent's lookback window), but can alternatively permanently store the data. The data store can accommodate multiple versions through a buffer system. In variants, the buffer system can implement version management through: separate databases/tables for each version, and/or version-specific caches with appropriate time-to-live settings determined by tag configurations. In an example, when performing canary deployments or rolling updates, the buffer architecture can enable quick version changes while maintaining state information required for inference, with version control managed through configuration files.

However, the optional data store may be otherwise configured.

The telemetry module can function to send data to the remote computing system for monitoring, training, other processes, and/or any other suitable purposes. The telemetry module preferably executes locally, but can alternatively execute remotely. In a first variant, the telemetry module can be a data diode (read only platform access). In a second variant, the telemetry module can enable read and/or write access. The telemetry module can send industrial system state, agent metadata, metrics, and/or any other suitable data types.

The telemetry module can send data to the remote computing system, wherein the data can include one or more of: raw data; tagged data (e.g., tagged by the tagging module); features (e.g., eigenfeatures); metrics, inference traces, higher class points, experiences (e.g., state-action-reward trajectories, etc.); action metadata; debugging artifacts; encoded data; and/or any other suitable data types.

The telemetry module can send the data to the remote computing system: in real time, at a predetermined frequency (e.g., every night, etc.), and/or any other suitable transmission timing.

However, the telemetry module may be otherwise configured.

The learning module can function to update the agent, learn a control model, and/or any other suitable functions. The learning module can receive feedback in the form of rewards or penalties from the environment based on the setpoints determined (e.g., commanded) by the local agent. A remote version of the agent can maintain a policy that maps states to actions, learning to maximize cumulative rewards over time (e.g., through the local agent's trial and error exploration). The learning module can continuously update this policy using algorithms such as Q-learning or policy gradients, and/or any other suitable learning algorithms. The learning module can gradually improve its decision-making capabilities by balancing exploration of new actions with exploitation of known successful strategies and/or any other suitable optimization approaches. In a first variant, the learning module can be local to the industrial system. In a second variant, the learning module can be remote (e.g., on cloud platform), wherein the resultant remote agent and/or parameters thereof can be packaged and sent to the local system as a new agent version for local execution.

However, the learning module may be otherwise configured.

However, the ML control system may be otherwise configured.

### 3. Method

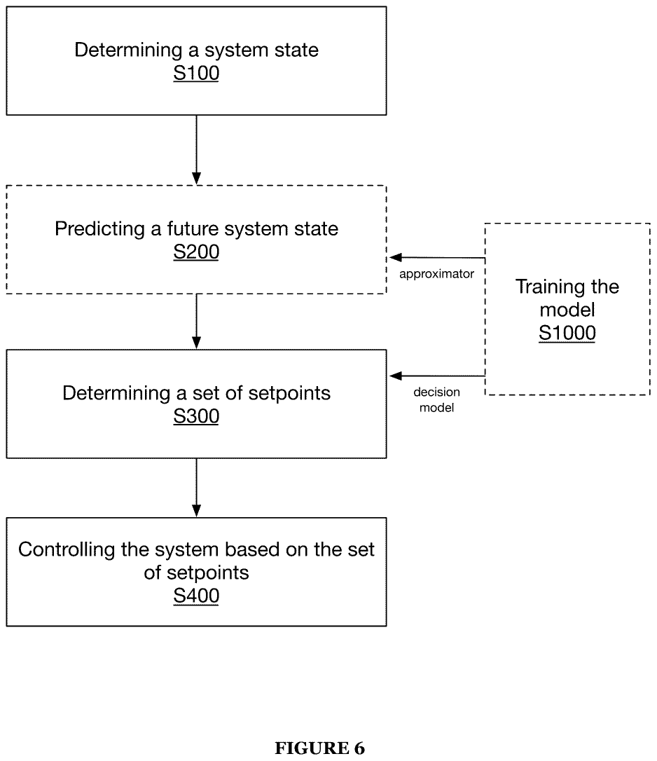

As shown in FIG. 6, the method can include: determining a system state S100; optionally determining a future system state S200; determining a set of setpoints S300; controlling the system based on the set of setpoints S400; and optionally training the model S1000. The method functions to control the industrial facility 1000 (e.g., data center), as previously described. The method is preferably performed by or using the system previously described, but can additionally or alternatively be performed by or using any other system. The method more preferably controls the secondary cooling loops (e.g., a set of coolant distribution units), but can additionally or alternatively control a larger or smaller thermal domain or control domain. The method can be performed continuously, intermittently, periodically, sporadically, and/or in any suitable manner.

Determining a system state S100 functions to determine a set of values and/or parameters that describe the system. S100 more preferably determines a supply temperature of a cooling loop, but can alternatively include determining a return temperature, an ambient temperature, a flow rate, or any other suitable system state. In variants, a supply temperature can refer to a temperature of the cooling loop fluid after absorbing heat from the associated rack. In variants, S100 can include measuring values using sensors (e.g., temperature sensors, pressure sensors, flow sensors, etc.). Examples of sensor measurements can include temperature, pressure, flow rates, humidity, power signal, voltage, current, and/or any other sensor measurement. The temperature can include ambient temperature, supply temperature, return temperature, computation hardware temperature, etc. The power signal can include the power signal of a system component, computation hardware, or computing device, etc.

The system state can be measured, retrieved, and/or otherwise collected via an in-band IT network, an out-of-band IT network, OT network, or any suitable network. In variants, the in-band IT network can be an information-technology network that communicates with the computation hardware through the same communication pathways used for user/application traffic. For example, the in-band IT network can include the internal server network interfaces, top-of-rack (ToR) switches, or other data paths used by the computing devices. Information obtained via the in-band IT network can include device-reported telemetry such as CPU utilization, rack-level and/or server-level power consumption, component temperatures reported through system management interfaces (e.g., via IPMI-over-LAN, Redfish over HTTP), or any other operational metrics available through host-side software. In some variants, the system can use the rack-level power measurement obtained via the in-band IT network as part of determining the system state.

In variants, the out-of-band IT network can be a logically or physically separate management network that provides access to platform management controllers of the computing devices. For example, the out-of-band IT network can include baseboard management controllers (BMCs), chassis management controllers, or remote management interfaces (e.g., IPMI, Redfish, iLO, iDRAC). Information obtained via the out-of-band IT network can include server and rack telemetry such as power draw, inlet temperature, outlet temperature, fan speed, component health indicators, or any other management-level metrics exposed by the platform hardware. In some variants, rack-level power telemetry obtained from BMCs or other management controllers can be used when determining the system state.

In variants, the OT network can be an operational-technology network that connects facility-level equipment, such as cooling system components and environmental sensors. For example, the OT network can include industrial fieldbuses, programmable logic controllers (PLCs), supervisory control and data acquisition (SCADA) systems, building-management systems (BMS), and/or any other infrastructure-level control networks. Information obtained via the OT network can include temperatures (e.g., supply temperature, return temperature), flow rates, pressures, pump speeds, valve positions, chiller setpoints, facility power measurements, and/or any other infrastructure telemetry. In variants, the OT network provides the primary sensor data for determining cooling-loop conditions (e.g., supply/return temperatures and flow rates).

In variants, a system state can include the system's current and/or previously determined setpoints. The setpoints can include chiller temperature setpoints, fan speed, valve position, flow rate setpoints, pressure setpoints, and/or any other setpoints. System states (e.g., sensor measurements, setpoints, etc.) determined in S100 can be stored (e.g., to create a time series of system states, etc.) or can be updated and/or replaced. S100 can be performed continuously, periodically, intermittently, sporadically, and/or at any other frequency.

However, determining a system state S100 may be otherwise performed.

The method can optionally include determining a future system state S200, which functions to determine future system parameters and/or values based on the system state. S200 more preferably determines a future thermal load and/or future temperature profile of the cooling system, but can alternatively include predicting a future return temperature, supply temperature, coolant temperature rise, heat rejection requirement, expected thermal response to a power change, or any other predicted thermal behavior based on the system state. S200 can be performed by a state approximator, a predictive model, and/or any type of model. The state approximator can include a machine learning model (e.g., neural network, multilayer perceptron model, convolutional neural network, recurrent neural network, etc.), a physics-based model, a statistical model (e.g., linear regression, logistic regression, Poisson regression, time series model, etc.), a triangle model, a probabilistic model, a hybrid model, and/or any other model.

The state approximator can be trained and/or learned to determine (e.g., predict, estimate, compute, etc.) a future thermal load, temperature (e.g., computation hardware temperature, chiller fluid temperature, ambient temperature, etc.), a thermal latency and/or thermal response time, time delay between power spike and setpoint action start (e.g., valve action, valve position change, etc.), time delay between action start and top of the setpoint spike (e.g., lowest point of temperature setpoint), time delay until system reaches stability or equilibrium, an anticipated power load and/or power consumption, and/or any other suitable system state.

In variants, the state approximator can determine (e.g., predict, compute, estimate, etc.) a global system state, average system state, and/or a local system state. In examples of the variants, local system states can include a return and/or supply temperature of a specific CDU, a temperature of a computation hardware, an ambient temperature in a specific region of the industrial facility, or any other suitable local system states. An average system state can include an average temperature across a plurality of racks, an average return and/or supply temperature of a plurality racks, an average temperature of computation hardware within a region of the industrial facility, or any other suitable average system state. A global system state can include a total thermal load of the data center, a total power consumption of the computation hardware and cooling infrastructure, a global temperature distribution across the data center, a total coolant return temperature, or any other suitable global system state.

In variants, the state approximator can receive a system state (e.g., set of return temperatures, supply temperatures, computation hardware temperatures, chiller temperatures, flow rates, chiller temperatures, ambient temperatures, power signal, etc.) as input and compute a future system state based on the system state. In variants, the input can include a time-series of system states. For example, the input to the approximator can include a set of temperatures from a previous set of time steps. In variants, the input can include system states from the past 10 minutes, the past 30 minutes, the past hour, and/or any other suitable amount of time. In an example, the state approximator can receive a power signal of a rack (e.g., computation hardware, etc.) and a supply temperature of the loop, predict a thermal load based on the power signal, and compute supply temperature setpoint based on the predicted thermal load. In a specific example, the temperature setpoint can be a value lower than a current setpoint in order to preemptively cool the system. In variants in which the thermal load is predicted using a set of coefficients, parameters, and/or weights, the method can optionally include comparing the measured supply temperature and the temperature setpoint and updating the coefficients, parameters, and/or weights based on the deviation.

In variants, the input to the approximator can include system and/or system component properties and/or hyperparameters. In examples, properties can include computation hardware performance limits (e.g. threshold temperature), number of chillers, number of computation hardware, types of computation hardware, and/or any other properties. Utilizing system properties as input can allow for more accurate predictions by incorporating system-based considerations for determining a future system state. For example, systems with larger amounts of computation hardware can have a different future system state (e.g., thermal response, etc.) than a system with less computation hardware.

The future system state can be computed, calculated, predicted, inferred, interpolated, or otherwise determined. The future state can be a system state that is between 10 seconds and multiple hours into the future (e.g., 10 seconds, 30 seconds, 1 minute, 2 minutes, 5 minutes, 10 minutes, 15 minutes, 30 minutes, 1 hours, 2 hours, 3 hours, 4 hours, 5 hours, 12 hours, or any value and/or range therebetween).

In a specific variant, S200 can include a state approximator that can be a model that represents time-dependent responses (e.g., temperature and/or power consumption) as triangular waveforms, parameterized by slopes, temporal parameters, and/or magnitudes (e.g., triangle model). In these variants, the triangle waveforms can represent accumulation and dissipation of heat and/or increases and decreases in power consumption. In variants, the integral of the triangle (e.g., the area under the curve) can represent a total expected heat load. The triangle model can be used to predict a future thermal response to a system perturbation (e.g., predetermined power spike, predetermined amount of compute, etc.). In variants, the parameters of the triangle model can be learned or tuned during model training, be predetermined (e.g., before deployment), and/or be otherwise determined. In variants, the triangle model coefficients (e.g., slopes, temporal parameters, etc.) can be learned and/or tuned via reinforcement learning. In a specific example, the triangle model can determine a thermal load which can be used to determine a supply temperature setpoint. A difference between the measured supply temperature and temperature setpoint can be used as a reward signal. Based on this difference, the coefficients of the model can be tuned using policy gradient based parameter tuning, gradient based optimizers, Q-learning, value-based parameter tuning, and/or any other suitable method or algorithm.

In a second specific variant, the model can be a physics-based model. In this variant, the model can include a set of physics-based equations (e.g., partial differential equations, etc.) used to compute a future temperature, heat, pressure, and/or any other value. In examples of the second specific variant, equations can include heat transfer equations (e.g., Fourier's law of heat conduction, convective heat transfer equations), fluid dynamics equations (e.g., Navier-Stokes equations), energy balance equations, and thermodynamic relations (e.g., ideal gas law, conservation of energy equations), or any other suitable physics-based equations.

In a third specific variant, the model can be a machine learning model, where the model is trained to determine a future system based on system state inputs. In variants, the machine learning model can include linear layers, convolution layers, max pool layers, attention mechanisms, recurrent layers, normalization layers, activation functions, dropout layers, residual connections, embedding layers, graph convolutional layers, transformer blocks, generative layers, and/or any other suitable machine learning model layer and/or module.

However, the state approximator can be any other suitable model.

In variants, S200 can use different state approximators and/or models to predict future system states for different regions and/or components of the industrial system. In variants, predicting a future system state can include selecting a model based on the future system, subsystem, and/or component of interest. In these variants, the model can be selected from a set of models, each model trained to determine a future system of a specific component, region, and/or subsystem of the industrial facility. In a variant, a specific state approximator can be used to calculate the future system state of a specific component and/or subsystem of the industrial system (e.g., a specific CDU, a specific rack and/or pod, etc.). In an example, each cooling loop is associated with a control agent that has a state approximator for each component (e.g., CDU, etc.) of the cooling loop. In this variant, each state approximator receives, as input, a supply and/or return temperature of the associated component (e.g., CDU, etc.), and determines a predicted heat load. Setpoints are determined for each component based on the heat loads. In these variants, different affinities of the system can be learned. Affinities can refer to learned transfer functions of different components of the system. For example, within a cooling loop, CDUs can have different thermal responses (e.g., due to location, architecture, system structure, etc.). In variants, in which each CDU is modeled by its own specifically tuned and/or learned state approximator, these different affinities can be learned. However, a plurality of state approximators can be otherwise utilized.

However, determining a future system state S200 may be otherwise performed.

Determining a set of setpoints S300 functions to compute a set of setpoints based on the system state and/or future system state. S300 can be performed after S100 and/or S200. In variants, S300 can be determined periodically, intermittently, continuously, in-response to a request, and/or in any suitable manner. In a specific example, setpoints can be determined at a specific frequency related to the physical and/or operational constraints of the industrial system. For example, in variants a chiller temperature can only be modified once every hour. Therefore, in this example, a setpoint can be determined once every hour. However, in variants, setpoints can be determined every minute, every 5 minutes, every 10 minutes, every 15 minutes, every 30 minutes, every hour, every 2 hours, every 5 hours, every 10 hours, every 12 hours, or at any range and/or value therebetween. In other variants, setpoints can be determined any time the industrial facility is assigned a new task, job, operation, and/or other assignment. In another variant, setpoints can be determined in response to a sensor measuring a threshold value. For example, setpoints can be determined if a computation hardware temperature or return temperature exceeds a threshold value. However, setpoints can be determined at any time.

The setpoints can include a chiller setpoint temperature, a supply temperature, a return temperature, a flow rate (e.g., supply flow rate, CDU-specific flow rates, etc.), a pressure, a valve position (e.g., CDU primary-secondary control valve, mixing valve, isolation valve, secondary loop supply valve, secondary loop return valve, rack manifold control valves, etc.), a fan speed, an ambient air temperature, and/or any other setpoint.

In variants, S300 can include determining the setpoints based on the system state (e.g., determined in S100), predicted future states (e.g., determined in S200), system properties and/or hyperparameters, and/or any other information. In variants, S300 can determine the setpoints based on computation hardware performance limits (e.g. threshold temperature, T-limits), number of chillers, number of computation hardware, types of computation hardware, and/or any other properties. For example, setpoints can be determined based on constraints, requirements, and/or conditions established by the structure, architecture, and/or components of the industrial system. In a specific example, a T-limit of a computing device (e.g., GPU) can be used as setpoint constraint (e.g., upper limit) such that the determined setpoints do not violate the constraint.

In variants, S300 can include determining setpoints based on a subset of the system states. For example, in variants setpoints for a specific subsystem or component (e.g., a specific CDU, a specific cooling rack, a specific cooling loop, etc.) may only be determined based on system states associated with that subsystem. In an example, setpoints for each technical cooling loop can be determined based solely on the system states associated with that specific loop. For instance, a given technical loop can include a set of CDUs, rack manifolds, and associated supply/return lines. The model can receive only the temperatures, flow rates, pressures, and actuator states for that loop, and determine loop-specific setpoints based on the states of the cooling loop. In this example, each technical loop is treated as an independent subsystem, and its setpoints are determined using only the sensor data and/or and states corresponding to that loop's components. In variants, the independence of each technical loop can be implemented using physical isolation mechanisms, logical isolation mechanisms, software isolation mechanisms, and/or isolation mechanisms. Through these mechanisms, a control model and/or agent receives only the system states associated with that loop and is unable to ingest or process telemetry from unassociated loops, thereby enabling the cooling loop control independence. For example, each loop can include a dedicated OT network segment (e.g., a loop-specific fieldbus, VLAN, or subnet) that carries only the telemetry and control signals for the CDUs, rack manifolds, valves, and sensors associated with that loop. In variants, network-level access-control rules (e.g., firewall rules, ACLs, device-ID whitelists) can prevent cross-loop traffic from being routed to the module. In some variants, a data-aggregation layer (e.g., a loop-local data broker or edge controller) can expose only loop-specific variables (e.g., supply/return temperatures, flow rates, pressures, actuator statuses) to the module through a restricted API or schema defining the allowable input fields. In variants, the controllers and/or CDUs of each loop can be physically isolated through separate communication interfaces (e.g., distinct Ethernet links, serial buses, or non-bridged OT backplanes), such that telemetry from other loops is not electrically or logically accessible. In variants, the model for setpoint determination (e.g., agent, control model, decision model, etc.) may only receive (e.g., via transmission, etc.) system states associated with subsystems. However, in other variants, the module may receive the system states of unassociated subsystems, but may otherwise exclude them during determination of setpoints.

In variants, S300 can be performed using a model (e.g., a decision model, a decision module, a setpoint-determination model), using heuristics, rules, and/or policies, through optimization of a set of equations and/or constraints based on the system (e.g., minimizing power consumption, minimizing average temperature, maximizing heat absorption, etc.), and/or any suitable method. The models used for determining the setpoints can include a machine learning model (e.g., neural network, multilayer perceptron model, convolutional neural network, recurrent neural network, etc.), a physics-based model, a statistical model (e.g., linear regression, logistic regression, Poisson regression, time series model, etc.), a probabilistic model, a hybrid model, a lookup table, a heuristic, and/or any other model.

In a first variant, determining a set of setpoints S300 can include determining setpoints based on the predicted physical state of the approximator. In a specific example, the approximator can predict a future thermal load based on a power signal. The decision module can compute setpoints (e.g., supply and/or return temperatures, flow rates) that will accommodate and/or absorb the heat load (e.g., using a look-up table, predetermined setpoint-heat load relationships, using physics-based relationships, etc.). In a specific example, the approximator can predict a thermal load based on an upcoming power spike, and the decision module can proactively determine a lower supply temperature setpoint to increase available thermal transfer capacity. For instance, when a predicted thermal load exceeds a threshold, the decision module can compute a reduced supply temperature setpoint such that the cooling loop has additional temperature headroom to absorb the upcoming thermal load. By pre-cooling the secondary loop (e.g., decreasing the CDU supply temperature or increasing a CDU flow rate), the system can maintain outlet temperatures within allowable limits during the predicted power spike.

In a second variant, determining can include using a decision model, wherein the model can receive, as input, system states (e.g., as determined in S100), predicted future system states (e.g., as optionally determined in S200), and/or system properties and/or constraints, and determine (e.g., compute, calculate, predict, select, etc.) setpoints based off the input. In an example, the system state and predicted system states can be passed through the decision model. The decision model can then produce, as output, a set of setpoints.

In a third variant, when the setpoints are determined using heuristics, rules, and/or policies, a model can include a set of learned and/or predetermined rules and/or policies. In an example, a rule and/or policy can include reducing and/or increasing a setpoint (e.g., temperature, flow rate, pressure, fan speed, etc.) when a predetermined system state and/or predicted future system state is determined. However, the method can include using any other suitable rules and/or heuristics. In variants, these rules, heuristics, and/or policies can be manually determined (e.g., using domain knowledge), learned (e.g., through reinforcement learning), and/or otherwise established.

In a fourth variant, wherein setpoints are determined through optimization, determining setpoints can include finding an exact solution to an optimization problem, an optimal solution to an optimization, a sub-optimal solution to the optimization problem, a possible solution to the optimization, and/or any other possible solution. This solution can be determined through a search process (e.g., exhaustive search, branch-and-bound search, etc.), by mathematically solving the optimization problem (e.g. solving a system of equation), by applying a numerical optimization technique (e.g., gradient descent, convex optimization, stochastic optimization, or evolutionary optimization), by employing an approximation or relaxation of the optimization problem, by performing probabilistic inference (e.g., variational inference or Bayesian optimization), or otherwise solved. The optimization problem can include variables, constraints, governing equations, bounds, and/or any other component. For example, the optimization problem can include a set of variables, constraints, and governing equations, that collectively define the industrial system and relate the variables to a target optimization variable. The target optimization variables can include power consumption, temperature, cost, and/or any other target optimization variable. The temperature can include ambient temperature, component temperatures, average temperatures, supply temperature, return temperatures, etc. In these variants, setpoints can be variables of the optimization problem that can be determined (e.g., solved for) in order to optimize (e.g., minimize, maximize, etc.) the target optimization variable. In variants, setpoints (e.g., variables of the optimization problem) can be solved such that the setpoints obey the constraints, governing equations, and/or bounds of the optimization problem while optimizing the target optimization variable.

However, determining a set of setpoints S300 may be otherwise performed.

Controlling the system based on the set of setpoints S400 functions to operate the industrial system using the setpoints. S400 can be performed after setpoints are determined (e.g., after S300). S400 can include controlling one or more physical or virtual components of the industrial system (e.g., machinery, actuators, valves, motors, heaters, chillers, pumps, robotic arms, control modules, software-defined subsystems, etc.) based on the setpoints. S400 can be performed in real-time, near-real-time, at a scheduled time, in response to a trigger, or at any other time. S400 can be proactive, reactive, and/or otherwise performed. For example, the system can be proactively controlled to account for a predicted thermal load, power load, and/or any other future state. However, in other variants, the system can be controlled in response to a measured state (e.g., measured supply temperature, return temperature, etc.). In variants, S400 can be continuous, intermittent, or otherwise performed. In variants, S400 can include closed loop control, open-loop control, open-loop with periodic optimization updates, or any other control mechanism.

During S400, control commands can be sent through a supervisory control and data acquisition (SCADA) system, distributed control system (DCS), programmable logic controllers (PLCs), edge devices, cloud-based control software, or any suitable control architecture. S400 can include changing actuator positions, motor speeds, fan speeds, fluid flow rates (e.g., supply flow rate, individual CDU flow rates), temperature setpoints (e.g., chiller temperatures, ambient air temperatures), or other operational parameters based on the setpoints.

In some variants, S400 can include sending and/or transmitting control instructions through an operational-technology (OT) network, a building management system (BMS), a chiller control system, or a CDU-level control interface. For example, control instructions can be transmitted to programmable logic controllers (PLCs), CDU controllers, actuator drivers, pump controllers, or chiller control modules via the OT network. In some variants, control instructions can be routed through a BMS, which relays updated setpoints (e.g., chiller setpoints, valve positions, pump speeds) to the appropriate infrastructure components. In a further example, control instructions can be sent directly to a CDU via a CDU management interface (e.g., Modbus TCP, BACnet, or proprietary protocols) to adjust a supply flow rate, valve position, or coolant temperature. In another example, control instructions can be transmitted via an out-of-band IT network to device-level management controllers (e.g., BMCs, chassis controllers) to control server fans or other IT-side actuators. Any combination of OT-network control paths, BMS interfaces, CDU control loops, or OOB-IT management paths can be used to apply the setpoints to the industrial system. However, S400 can include any other suitable steps.

However, controlling the system based on the set of setpoints S400 may be otherwise performed.

The method can optionally include training the model S1000, which functions to determine coefficients and/or parameters of the models (e.g., approximator, decision model, etc.). S1000 can be performed periodically, intermittently, in-response to a request, sporadically, continuously (e.g., if the model is a reinforcement learning model, etc.) and/or at any suitable frequency. S1000 can involve models that can be trained offline (e.g. pre-trained, trained on external systems), online, a combination thereof, or otherwise trained. The models can be trained using supervised training, unsupervised training, reinforcement learning, and/or any suitable method. S1000 can use historical data (e.g., historical power signal data, historical temperature signals, etc.), synthetic data, and/or any suitable data.

In variants of the predictive models and/or approximators, S1000 can use training data that includes a set of system states with the training target being a future system state (e.g., future temperature, heat load, thermal response, etc.). In other variants, S1000 can include learning the coefficients of the predictive model and/or approximators via reinforcement learning. In these variants, the reward and/or penalty signal for the reinforcement learning can include deviations in the supply and/or return temperature (e.g., from a supply and/or return temperature setpoint, from a previously measured supply and/or return temperature, etc.). In an example, the approximator can predict a thermal and/or power load and the decision module can compute setpoints based on the thermal and/or power load. If a measured supply temperature deviates from an expected value, the approximator can be penalized and/or the coefficients can be tuned. For example, the difference between the measured supply temperature and expected temperature can be a reward signal in variants in which the approximator is learned via reinforcement learning. The coefficients of the model can be tuned using policy gradient based parameter tuning, gradient based optimizers, Q-learning, value-based parameter tuning, and/or any other suitable method or algorithm. In another variant, the reward and/or penalty signal can include deviation between the computation hardware temperature and a thermal limit and/or threshold (e.g., T-limit). In variants, the training data can also include system and/or component properties. In these variants, the model can be trained to predict a future state based on the components, architecture, structure, location within the industrial facility, and/or any other suitable facility property.

In variants, the method can include training multiple models and/or approximators. For example, in variants an approximator can be trained for every component. Training multiple models (e.g., based on components, architecture, structure, location, etc.) can result in increased accuracy by ensuring that each model learns the patterns, trends, and/or behaviors of specific subsystems, components, and/or regions within the industrial facility. S1000 can include performing gradient descent, stochastic optimization, evolutionary optimization, reinforcement learning, probabilistic inference, Bayesian inference, least-squares fitting or any other method to tune coefficients, parameters, weights, and/or any suitable values of the models. In one specific example in which the approximator is a triangle model, the parameters (e.g., slopes, magnitudes, temporal parameters, etc.) of the triangle waveform can be determined during S1000. In other variants, the triangle model can be continuously learned, tuned, and/or modified through reinforcement learning. In other examples, S1000 can include tuning the coefficients and/or weights of a multi-layer perceptron model to determine the future system state and/or setpoints. However, S1000 can be otherwise trained.

However, training the model S1000 may be otherwise performed.

All references cited herein are incorporated by reference in their entirety, except to the extent that the incorporated material is inconsistent with the express disclosure herein, in which case the language in this disclosure controls.

As used herein, “substantially” or other words of approximation can be within a predetermined error threshold or tolerance of a metric, component, or other reference, and/or be otherwise interpreted.

Optional elements in the figures are indicated in broken lines.

Different processes, subsystems, modules, and/or elements discussed above can be defined, performed, operated, and/or controlled by the same or different entities. In the latter variants, different subsystems can communicate via: APIs (e.g., using API requests and responses, API keys, etc.), requests, and/or other communication channels. Communications between systems can be encrypted (e.g., using symmetric or asymmetric keys), signed, and/or otherwise authenticated or authorized.

Alternative embodiments implement the above methods and/or processing modules in non-transitory computer-readable media, storing computer-readable instructions that, when executed by a processing system, cause the processing system to perform the method(s) discussed herein. The instructions can be manually defined, be custom instructions, be standardized instructions, and/or be otherwise defined. The instructions can be executed by computer-executable components integrated with the computer-readable medium and/or processing system. The computer-readable medium may include any suitable computer readable media such as RAMs, ROMs, flash memory, EEPROMs, optical devices (CD or DVD), hard drives, floppy drives, non-transitory computer readable media, or any suitable device. The computer-executable component can include a computing system and/or processing system (e.g., including one or more collocated or distributed, remote or local processors) connected to the non-transitory computer-readable medium, such as CPUs, GPUs, TPUS, microprocessors, or ASICs, but the instructions can alternatively or additionally be executed by any suitable dedicated hardware device.

Embodiments of the system and/or method can include every combination and permutation of the various elements (and/or variants thereof) discussed above, and/or omit one or more of the discussed elements, wherein one or more instances of the method and/or processes described herein can be performed asynchronously (e.g., sequentially), contemporaneously, concurrently (e.g., in parallel), or in any other suitable order by and/or using one or more instances of the systems, elements, and/or entities described herein. Components and/or processes of the following system and/or method can be used with, in addition to, in lieu of, or otherwise integrated with all or a portion of the systems and/or methods disclosed in the applications mentioned above, each of which are incorporated in their entirety by this reference.

As a person skilled in the art will recognize from the previous detailed description and from the figures and claims, modifications and changes can be made to the embodiments of the invention without departing from the scope of this invention defined in the following claims.

We claim:

1. An industrial system comprising:
a plurality of independent technical cooling loops, wherein each technical cooling loop is thermally connected to a set of computing devices, wherein each technical cooling loop comprises:
a set of fluidly connected cooling distribution units (CDUs); and
a set of sensors configured to determine a cooling loop state, wherein the cooling loop state comprises a set of temperatures of the technical cooling loop; and
a plurality of control agents, wherein each control agent is associated with a different technical cooling loop and a set of models, wherein each control agent is configured to:
receive the cooling loop state of the respective technical cooling loop and a power signal of the respective set of computing devices;
using the set of models, determine a set of cooling loop setpoints for the set of CDUs based on the cooling loop state of the respective technical cooling loop and the power signal of the respective set of computing devices, wherein the set of cooling loop setpoints is not determined based on the cooling loop states of other technical cooling loops; and
control the set of CDUs of the respective technical cooling loop according to the set of cooling loop setpoints.

2. The industrial system of claim 1, wherein the set of models associated with each control agent comprises a reinforcement learning model, wherein the reinforcement learning model comprises a set of policies, wherein the set of policies are continuously updated based on the cooling loop state.

3. The industrial system of claim 1, wherein the cooling loop state of a technical cooling loop is only transmitted to the control agent of the respective technical cooling loop.

4. The industrial system of claim 1, wherein the set of models associated with each control agent comprises an approximator configured to predict a thermal response based on the respective power signal and respective cooling loop state, wherein the control agent determines the set of cooling loop setpoints based on the thermal response.

5. The industrial system of claim 4, wherein the approximator comprises a set of parameters learned through reinforcement learning.

6. The industrial system of claim 1, wherein the plurality of control agents is out-of-band of an in-band IT network controlling operations executing on each set of computing devices.

7. The industrial system of claim 1, wherein the plurality of control agents receive data from an out-of-band network through a data diode.

8. The industrial system of claim 1, further comprising a facility agent, where the facility agent is configured to determine a set of facility setpoints based on each cooling loop state of the plurality of technical cooling loops and each power signal of each set of computing devices.

9. The industrial system of claim 8, wherein the facility agent is executed at a lower frequency than an execution frequency of the control agents.

10. The industrial system of claim 1, wherein each control agent is further configured to determine the set of cooling loop setpoints based on a performance metric of the respective set of computing devices.

11. The industrial system of claim 10, wherein the performance metric comprises a clock frequency.

12. The industrial system of claim 1, wherein the set of models associated with each control agent comprises a CDU-specific model for each CDU of the respective technical cooling loop, wherein the set of cooling loop setpoints comprise a setpoint for each CDU determined by each CDU-specific model.

13. The industrial system of claim 1, wherein the plurality of control agents is further configured to proactively lower a supply temperature setpoint.

14. A system comprising:
a cooling loop agent associated with a set of cooling distribution units (CDUs) in thermal connection with a set of computing devices, wherein the cooling loop agent comprises a set of thermal approximators, wherein each thermal approximator of the set of thermal approximators is associated with a CDU of the set of CDUs, wherein the cooling loop agent is configured to:
predict a thermal response for each CDU of the cooling loop using the associated thermal approximator, based on a power signal of the set of computing devices and a supply temperature of the respective CDU;
determine a set of cooling loop setpoints based on the predicted thermal response for each CDU; and
control the set of CDUs according to the cooling loop setpoints.

15. The system of claim 14, wherein each thermal approximator comprises a set of coefficients, wherein the cooling loop agent is further configured to update the set of coefficients of each thermal response approximator based on the thermal state of the respective CDU.

16. The system of claim 15, wherein the set of coefficients of each thermal approximator is updated using a reinforcement learning algorithm, wherein a reward signal used for the reinforcement learning algorithm is determined based on a difference between the supply temperature of the respective CDU and a predetermined supply temperature setpoint.

17. The system of claim 14, wherein the cooling loop agent is further configured to switch to a fault-responsive operation mode when an abnormal behavior of the set of CDUs is detected, wherein the fault-responsive operation mode can include determining a set of alternative cooling loop setpoints based on a fault-responsive set of rules.

18. The system of claim 14, wherein determining a set of cooling loop setpoints based on the predicted thermal response comprises lowering a current cooling loop setpoint by an amount correlated to a heat load defined by the predicted thermal response.

19. The system of claim 14, further comprising a facility agent, where the facility agent is configured to determine a set of facility setpoints based the on the power signal of the set of computing devices and the supply temperature of each CDU, wherein the facility agent performs at a lower frequency than a frequency of the control agents.

20. The system of claim 14, wherein the set of CDUs is thermally connected to a set of computing devices, wherein each control agent is further configured to determine the set of cooling loop setpoints based on a thermal limit of the set of computing devices.
